(19) United States
(12) Patent Application Publication
(10) Pub. No.: US 2010/0020400 A1
(43) Pub. Date: Jan. 28, 2010

(54) DIFFRACTIVE OPTICAL ELEMENT, METHOD FOR MANUFACTURING DIFFRACTIVE OPTICAL ELEMENT, AND LASER BEAM MACHINING METHOD

(75) Inventor: Jun AMAKO, Matsumoto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/265,761

(22) Filed: Nov. 6, 2008

(30) Foreign Application Priority Data
Nov. 6, 2007 (JP) 2007-289050
Oct. 31, 2008 (JP) 2008-281269

(51) Int. Cl. G02B 5/18; G03F 7/20

(52) U.S. Cl. 359/576; 430/321

(57) ABSTRACT

A diffractive optical element includes: a substrate having a first face and a second face; a diffractive structure section that is formed on the first face of the substrate, shaped in a rectangular form in a cross-sectional view of the diffractive structure section, and having an upper face and a plurality of protuberance portions; and a grid section that is formed of a dielectric material, formed on at least one of the upper face of the diffractive structure section and the second face of the substrate, and including micro protuberance portions that are smaller than each of the protuberance portions.

### CROSS-REFERENCE TO RELATED APPLICATION

This application is based on and claims priority from Japanese Patent Application No. 2007-289050, filed on Nov. 6, 2007, and Japanese Patent Application No. 2008-281269, filed on Oct. 31, 2008, the contents of which are incorporated herein by reference.

### BACKGROUND

1. Technical Field

The present invention relates to a diffractive optical element, a method for manufacturing a diffractive optical element, and a laser beam machining method.

2. Related Art

A technique of a laser beam machining by using a diffractive optical element has attracted attention.

For example, in Japanese Unexamined Patent Application, First Publication No. 2002-263876, the technique of laser beam machining is disclosed in which a laser light is incident into a diffractive optical element, the laser light is separated into a plurality of beams, and an object (work piece) is irradiated with these beams.

In the technique of a laser beam machining, a variety of workings such as drilling, cutting, or the like can be realized.

With regard to the diffractive optical element used in the foregoing laser beam machining, as much suppression of light from a surface of the diffractive optical element as possible has been desired.

The reason is that, the reflected light becomes stray light and an object and optical system may suffer unexpected damage by the stray light.

In order to suppress the foregoing reflected light, an anti-reflective film is generally formed on the surface of the diffractive optical element.

When the above-described laser beam machining is performed, it may be necessary to cause a high energy laser light (i.e., a high power laser) to be incident to a diffractive optical element in accordance with an object to be worked, the machining conditions, and the like. For example, the high energy laser light is used in the case of drilling a plurality of holes at the same time, cutting a plurality of regions, or the like.

When the above-described working is performed, for example, a high output pulse laser whose average output is greater than 100 W is used.

However, since the durability of the above-described anti-reflective film relative to a laser is approximately 40 W/cm² at the moment, there is a problem in that the anti-reflective film cannot resist a working that uses the high output pulse laser.

Furthermore, when a specified wavelength (e.g., ultraviolet region and infrared region) is used in a plurality of wavelength-bands of a laser light, there is a case in which a film material which can be used as an adequate anti-reflective does not exist.

Furthermore, an irregularity to the order of substantially several μm is formed on a surface of the diffractive optical element. Therefore, when a high energy laser light is incident onto the foregoing face having the irregularity, an electric field with a high level of intensity is concentrated in a specific portion of the irregularity, and the anti-reflective film may be damaged.

Therefore, a diffractive optical element that has an anti-reflective means with a high level of resistance and can also resist a high energy laser light has been desired.

### SUMMARY

An advantage of some aspects of the invention is to provide a diffractive optical element that has an anti-reflective means with a high level of resistance and can also resist a high energy laser light, and a manufacturing method thereof. Also, an advantage of this aspect of the invention is to provide a laser beam machining method, where it is possible to realize laser beam machining with a high level of productivity and reliability by using the diffractive optical element of the invention.

A first aspect of the invention provides a diffractive optical element including: a substrate having a first face and a second face; a diffractive structure section that is formed on the first face of the substrate, shaped in a rectangular form in a cross-sectional view of the diffractive structure section, and having an upper face and a plurality of protuberance portions; and a grid section that is formed of a dielectric material, formed on at least one of the upper face of the diffractive structure section and the second face of the substrate, and including micro protuberance portions that are smaller than each of the protuberance portions.

In the above-described diffractive optical element, an effect that the reflected light is suppressed occurs caused by action of the grid section whose size is smaller than each protuberance portion of the diffractive structure section. Also, the transmissive diffracted light includes an adequate and wide intensity distribution caused by action of the diffractive structure section.

By appropriately setting the arrangement of the irregularity of the diffractive structure section or the form in a plan view of the diffractive structure section, it is possible to control the formation and the intensity of the optical pattern depending on the purpose of use and the usage environment of the optical pattern caused by transmitted light.

That is, anti-reflective function and optical pattern production function are combined, and the diffractive optical element that has an anti-reflective means with a high level of resistance and that can also resist a high energy laser light is realized.

A second aspect of the invention provides a diffractive optical element including: a substrate having a first face and a second face; a diffractive structure section including an upper face and a plurality of protuberance portions that is formed on the first face of the substrate and shaped in a periodic curved surface form; and a grid section that is formed on at least one of the upper face of the diffractive structure section and the second face of the substrate, and including micro protuberance portions that are smaller than each of the protuberance portions.

In the above-described diffractive optical element, it is possible to obtain the same actions and effects as the foregoing constitution.

Furthermore, in the structure of the diffractive optical element of the second aspect, since the diffractive structure section is formed so as to have a periodic curved surface form, it is possible to prevent incidence light energy as high order diffracted light from leaking out, in contrast with the diffractive structure section that is rectangular in a cross-sectional view thereof.

A diffractive optical element in which light utilization efficiency is further enhanced is obtained.

In the above-described diffractive optical element of the first aspect and second aspect, it is preferable that each of the above-described micro protuberance portions of the above-described grid section be formed so as to extend, for example, in one direction.

That is, it is possible to form the grid section as a one-dimensional grid (reticular pattern).

In the case of forming the grid section as a one-dimensional grid, it is preferable that an extension direction of each of the above-described protuberance portions of the diffractive structure section be substantially parallel to an extension direction of each of the above-described micro protuberance portions of the grid section.

In addition, it is preferable that an extension direction of each of the above-described protuberance portions of the diffractive structure section be intersected with an extension direction of each of the above-described micro protuberance portions of the grid section.

In the case where each of the recessed portions and the protuberance portions is intersected with each micro protuberance portion, it is possible to easily form the micro protuberance portion adjacent to a step-difference between each of the recessed portions and each of the protuberance portions.

The angle at which each of the recessed portions and the protuberance portions is intersected with each micro protuberance portion is optionally set. For example, the angle can be set to 45° or to a multiple thereof, such as 90°, 135°, or the like.

In the above-described diffractive optical element of the first aspect and second aspect, it is preferable that each of the above-described micro protuberance portions of the above-described grid section be arrayed so as to be two-dimensionally distributed.

That is, it is possible to form the grid section as a two-dimensional grid (reticular pattern).

In this case, it is not necessary for the distance between each of the micro protuberance portions to be constant.

According to the micro protuberance portion formed in the foregoing two-dimensional grid form, it is possible to further increase the effect of the reflected light being suppressed.

In the above-described diffractive optical element of the first aspect and second aspect, it is preferable that the depth of the above-described grid section be less than the depth of the diffractive structure section.

This relationship is clearly identified based on formula (2) and formula (3) indicated in a first embodiment described below.

That is, the diffractive optical element of the invention is designed based on the formula (2) determining the structure of the grid section for obtaining a desired effect of the reflected light being suppressed, and the formula (3) determining the structure of the diffractive structure section for obtaining a desired diffraction characteristic. This diffractive optical element satisfies the above-described relationship.

In the above-described diffractive optical element of the first aspect and second aspect, for example, the above-described diffractive structure section operates to separate the above-described incidence light into a plurality of beams.

In the case in which the diffractive structure section operates to separate light into the beams, it is necessary to cause high energy light to be incident into the diffractive optical element in order to cause each of the separated beams to have a sufficient intensity.

Since the diffractive optical element of the first aspect and second aspect of the invention includes a function for suppressing the reflected light in addition, the diffractive optical element is particularly suitable to the foregoing application.

A third aspect of the invention provides a laser beam machining method including: preparing a diffractive optical element including a substrate having a first face and a second face, a diffractive structure section that is formed on the first face of the substrate, shaped in a rectangular form in a cross-sectional view of the diffractive structure section, having an upper face and a plurality of protuberance portions, and is capable of separating light that is incident into the diffractive structure section into a plurality of beams, and a grid section that is formed of a dielectric material, formed on at least one of the upper face of the diffractive structure section and the second face of the substrate, and including micro protuberance portions that are smaller than each of the protuberance portions; and causing a laser light to be incident into the diffractive optical element so that the laser light is separated into a plurality of beams and so that an object is irradiated with the beams.

A fourth aspect of the invention provides a laser beam machining method including: preparing a diffractive optical element including a substrate having a first face and a second face, a diffractive structure section that includes an upper face and a plurality of protuberance portions that is formed at a position which is close to the first face of the substrate and shaped in a periodic curved surface form, and is capable of separating light that is incident into the diffractive structure section into a plurality of beams, and a grid section that is formed on the at least one of the upper face of the diffractive structure section and the second face of the substrate, and including micro protuberance portions that are smaller than each of the protuberance portions; and causing a laser light to be incident into the diffractive optical element so that the laser light is separated into a plurality of beams and so that an object is irradiated with the beams.

According to the above-described laser beam machining method, when a plurality of places of an object is irradiated with the beam so that a variety of workings is performed, it is possible to sufficiently enhance the energy of the laser light to be incident thereinto.

The reason is that, due to the anti-reflective function by the grid section, it is possible to suppress stray light that causes damage to an optical system and an object (work piece).

As a result, it is possible to realize the laser beam machining with a high level of productivity and reliability.

Furthermore, by applying this laser beam machining method, it is possible to realize the laser beam machining apparatus with excellence cost performance.

A fifth aspect of the invention provides a method for manufacturing a diffractive optical element. The method includes preparing a substrate having a first face and a second face; forming a plurality of protuberance portions on the first face; forming a photosensitive film covering the protuberance portions on the first face; disposing liquid so as to cover the photosensitive film with the liquid whose refractive index is greater than 1 and is less than or equal to a refractive index of the photosensitive film; disposing a transparent parallel plate so as to face to the substrate with the liquid interposed therebetween; exposing the photosensitive film via the parallel plate and the liquid; developing the photosensitive film after removing the liquid and the parallel plate; etching the substrate using a pattern of the photosensitive film as a mask; and obtaining a diffractive optical element including: a diffractive structure section having a plurality of protuberance portions formed on the first face of the substrate, and a grid section that is formed of a dielectric material, formed on an upper face of the diffractive structure section, and including micro protuberance portions that are smaller than each of the protuberance portions.

A sixth aspect of the invention provides a method for manufacturing a diffractive optical element. The method includes preparing a substrate having a first face and a second face; forming a plurality of protuberance portions on the first face; forming a photosensitive film covering the protuberance portions on the first face; disposing a water soluble film so as to cover the photosensitive film with the water soluble film whose refractive index is greater than 1 and is less than or equal to a refractive index of the photosensitive film; exposing the photosensitive film via the water soluble film; developing the photosensitive film; etching the substrate using a pattern of the photosensitive film as a mask; and obtaining a diffractive optical element including: a diffractive structure section having a plurality of protuberance portions formed on the first face of the substrate, and a grid section that is formed of a dielectric material, formed on an upper face of the diffractive structure section, and including micro protuberance portions that are smaller than each of the protuberance portions.

In the above-described manufacturing method of the fifth aspect and the sixth aspect, the liquid whose refractive index is greater than air or a water soluble film that is equal thereto is disposed on the photosensitive film, and laser interference exposure is performed in this condition.

Due to the liquid or the water soluble film is disposed, the difference of a refractive index between the photosensitive film and a medium (liquid and parallel plate) that touches thereto becomes small, compared with the case in which interfering light is directly incident into the photosensitive film (i.e., case of exposing in a state in which air touches to the photosensitive film).

As a result, diffraction of the interfering light caused by irregularities of a surface of the photosensitive film are suppressed, and it is possible to avoid disorder of the intensity distribution of interfering light in the photosensitive film.

Therefore, according to the manufacturing method of the invention, reliable exposure onto a surface is realized even if the evenness of the surface is low, and it is possible to manufacture the diffractive optical element with high quality.

Furthermore, in the above-described method for manufacturing the diffractive optical element of the fifth aspect, it is preferable that the parallel plate include an anti-reflective film formed on a face of the parallel plate into which light exposing the photosensitive film is incident.

As a result, the reflected light generated on a surface of the parallel plate is suppressed, and it is possible to further reduce irregularities of exposure.

In the above-described method for manufacturing the diffractive optical element of the sixth aspect, it is preferable that the developing of the above-described photosensitive film be performed after removing the above-described water soluble film.

Furthermore, it is also possible to develop the photosensitive film without eliminating the water soluble film.

That is, the removal of the water soluble film before the development of the photosensitive film is not essential.

In the case in which the developing is performed while the water soluble film is provided, a pattern is formed on the photosensitive film, and it is possible to also dissolve the water soluble film at the same time.

### BRIEF DESCRIPTION OF THE DRAWINGS

FIG. 1 is a schematic cross-sectional view showing a cross-sectional structure of an optical element of a first embodiment.

FIGS. 2A and 2B are enlarged schematic perspective views showing a part of a grid section.

FIGS. 3A and 3B are enlarged schematic perspective views showing a part of a diffractive structure section.

FIGS. 4A, 4B, and 4C are enlarged schematic perspective views partially showing the diffractive structure section and the grid section.

FIG. 5 is an enlarged schematic cross-sectional view showing the diffractive structure section and a part of the grid section.

FIGS. 6A, 6B, 6C, and 6D are schematic cross-sectional views showing a method for manufacturing a diffractive optical element.

FIG. 7 is a schematic cross-sectional view showing a cross-sectional structure of a diffractive optical element of other embodiment.

FIG. 8 is a schematic perspective view showing a structure of a laser beam machining apparatus using the diffractive optical element.

FIG. 9 is a schematic cross-sectional view showing a cross-sectional structure of a diffractive optical element of other embodiment.

FIG. 10 is a schematic cross-sectional view showing a cross-sectional structure of a diffractive optical element of other embodiment.

FIGS. 11A, 11B, 11C, and 11D are schematic cross-sectional views showing a manufacturing method of a first modified example.

FIGS. 12A and 12B are schematic cross-sectional views showing a manufacturing method of the first modified example.

FIGS. 13A and 13B are schematic cross-sectional views showing a manufacturing method of a second modified example.

FIG. 14 is a schematic cross-sectional view showing a cross-sectional structure of an optical element of a second embodiment.

FIGS. 15A and 15B are enlarged schematic perspective views showing a part of a diffractive structure section.

FIGS. 16A, 16B, and 16C are enlarged schematic perspective views partially showing the diffractive structure section and the grid section.

FIG. 17 is an enlarged schematic cross-sectional view showing the diffractive structure section and a part of the grid section.

FIG. 18A is a diagram illustrating an example of the relationship between reflectance of a diffractive optical element 401 and the depth of a recessed portion (the height of micro protuberance portion 404a) of a grid section 404, in the case of using incidence light of TE-polarization.

FIG. 18B is a diagram illustrating an example of the relationship between reflectance and the depth of the recessed portion, in the case of using incidence light of TM-polarization.

FIG. 18C is an enlarged cross-sectional view of a micro protuberance portion 404a where reference numeral f is the filling rate of the grid section 404 and formula f=w/P using the pitch P and the width w of micro protuberance portion 404a is expressed.

FIG. 19 is a diagram illustrating an example of a cross-sectional form of the diffractive structure section, corresponding to a cross-sectional form of a diffractive structure section 403 in the X direction shown in FIG. 15A, and showing a pitch component of the irregularity structure of the diffractive structure section 403.

FIGS. 20A, 20B, 20C, and 20D are examples of schematic flow sheets of a method for manufacturing a diffractive optical element.

FIG. 21 is a schematic cross-sectional view showing a cross-sectional structure of a diffractive optical element of other embodiment.

FIG. 22 is a schematic cross-sectional view showing a cross-sectional structure of a diffractive optical element of other embodiment.

FIG. 23 is a schematic cross-sectional view showing a cross-sectional structure of a diffractive optical element of other embodiment.

### DESCRIPTION OF EXEMPLARY EMBODIMENTS

Hereinafter, embodiments of the invention will be described with reference to the drawings.

In the respective drawings, in order to make the respective components be of understandable size in the drawing, the dimensions and the proportions of the respective components are modified as needed compared with the real components.

### First Embodiment

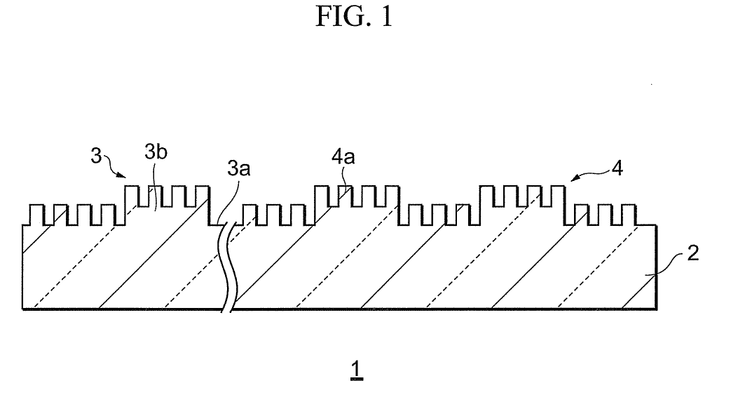

FIG. 1 is a schematic cross-sectional view showing a cross-sectional structure of a diffractive optical element of one embodiment in which the invention is applied.

The diffractive optical element 1 (optical element) of this embodiment shown in FIG. 1 includes a substrate 2, a diffractive structure section 3, and a grid section 4 (non-diffractive structure section).

The substrate 2 is a transparent substrate through which a wavelength of incidence light can pass.

A substrate made from inorganic material, for example, a glass substrate (quarts glass substrate) or the like is used as the substrate 2.

The thickness of the substrate 2 is, for example, approximately 1.2 mm.

The diffractive structure section 3 is provided on a first face of the substrate 2.

In addition, a second face of the substrate 2 is a plane as shown in the figure.

The diffractive structure section 3 is provided on the first face of the substrate 2.

This diffractive structure section 3 includes recessed portions 3a and protuberance portions 3b that are alternately arrayed.

Furthermore, as a matter of convenience in the figure, one of the recessed portions 3a and one of the protuberance portions 3b are represented by the corresponding reference numerals.

The diffractive structure section 3 constituted by the recessed portions 3a and the protuberance portions 3b is rectangular in a cross-sectional view thereof as shown in the figure.

Furthermore, the diffractive structure section 3 may be shaped in a form including a little taper.

In this embodiment, the diffractive structure section 3 is formed by working the first face of the substrate 2.

That is, the substrate 2 and the diffractive structure section 3 are constituted so as to become one body.

The grid section 4 is provided on the first face of the substrate 2 and along an upper face of the diffractive structure section 3.

The grid section 4 of this embodiment is formed so as to be unified with the above-described substrate 2 and the diffractive structure section 3.

This grid section 4 includes a plurality of micro protuberance portions 4a. The size of the micro protuberance portion 4a is smaller than each of the protuberance portions 3b of the above-described diffractive structure section 3.

Each of the micro protuberance portions 4a is made of a dielectric material.

In this embodiment, the constituent material of each micro protuberance portion 4a is a quarts glass.

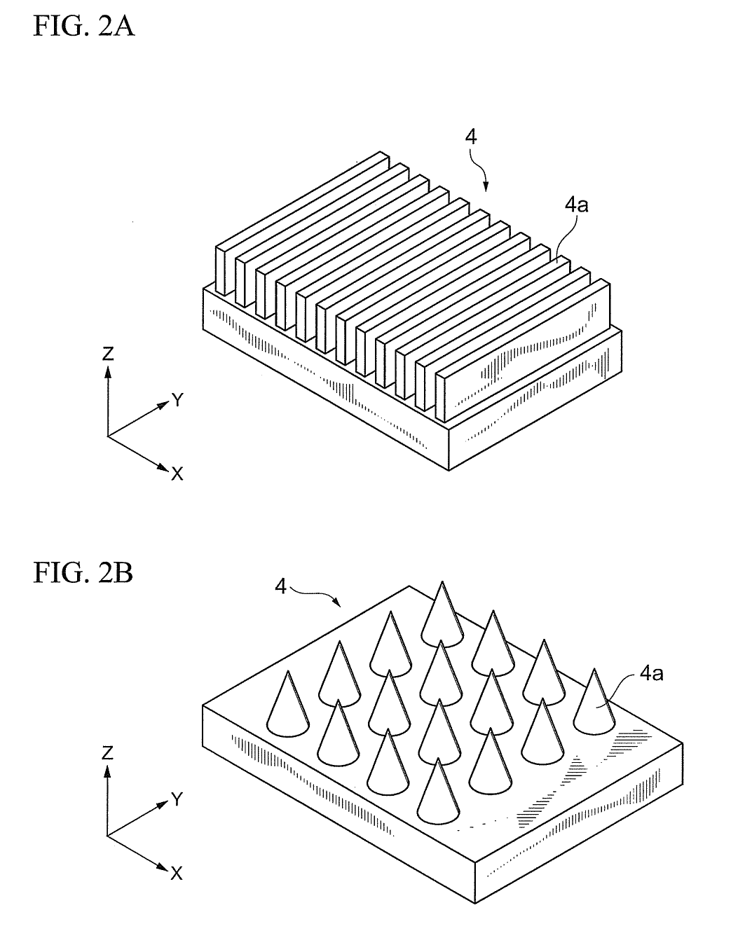

FIGS. 2A and 2B are enlarged schematic perspective views showing a part of the grid section 4.

Each of the micro protuberance portions 4a of the grid section 4 is, for example, a structure body shaped in a stripe form as shown in FIG. 2A, that is extended in one direction (Y direction shown in the figure).

These micro protuberance portions 4a are periodically arrayed along, for example, the X direction.

Furthermore, each of the micro protuberance portions 4a is not limited to a one-dimensional grid as shown in FIG. 2A, may be arrayed in a matrix form (two-dimensional grid) as shown, for example, in FIG. 2B.

In this case, the distance between each of the micro protuberance portions 4a may be constant. Alternatively, it is not necessary for the distance to be constant.

Furthermore, in FIG. 2B, as an example of the micro protuberance portion 4a, a cone form is shown. However, the form of the micro protuberance portion 4a is not limited thereto.

The form of the micro protuberance portion 4a may be any of a hemispherical form, a pyramid form, a pillar form, or the like.

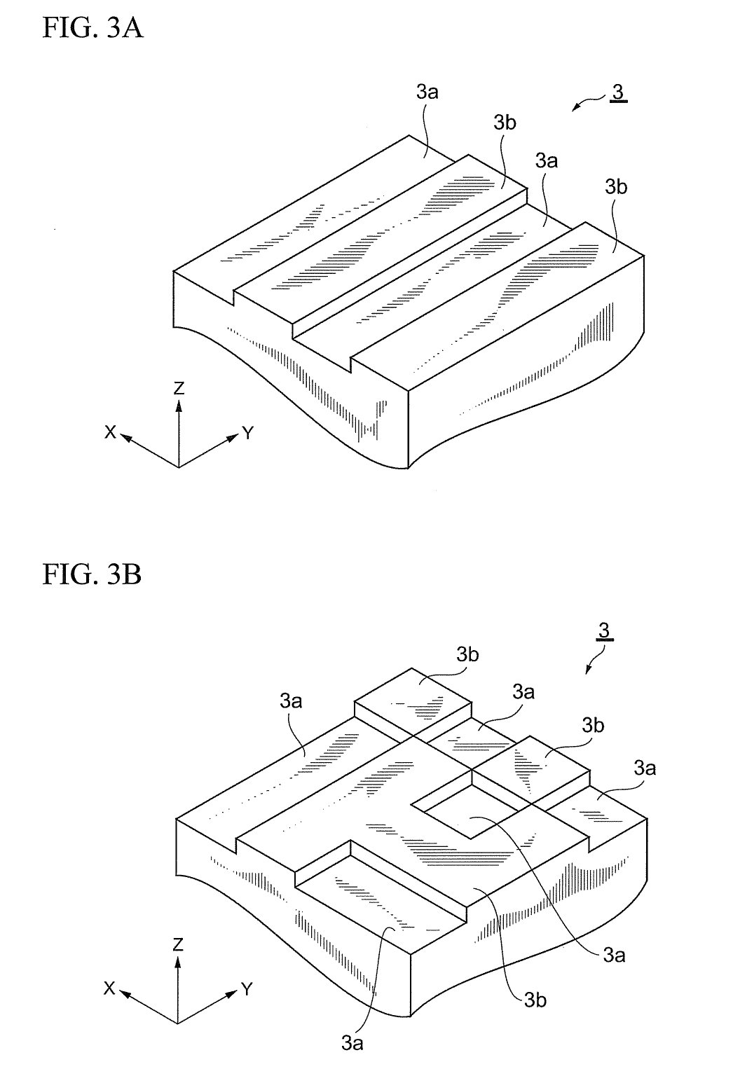

FIGS. 3A and 3B are enlarged schematic perspective views showing a part of the diffractive structure section 3.

As shown in FIG. 3A, the diffractive structure section 3 includes recessed portions 3a and protuberance portions 3b that are extended in one direction (the Y direction shown in the figure).

These recessed portions 3a and the protuberance portions 3b are shaped in a stripe form as shown in the figure and are periodically arrayed along the X direction.

Furthermore, each of the recessed portions 3a and the protuberance portions 3b is not limited to a one-dimensional arrangement (one-dimensional grid) as shown in FIG. 3A. Each of the recessed portions 3a and the protuberance portions 3b may be a two-dimensional arrangement (two-dimensional grid) as shown, for example, in FIG. 3B.

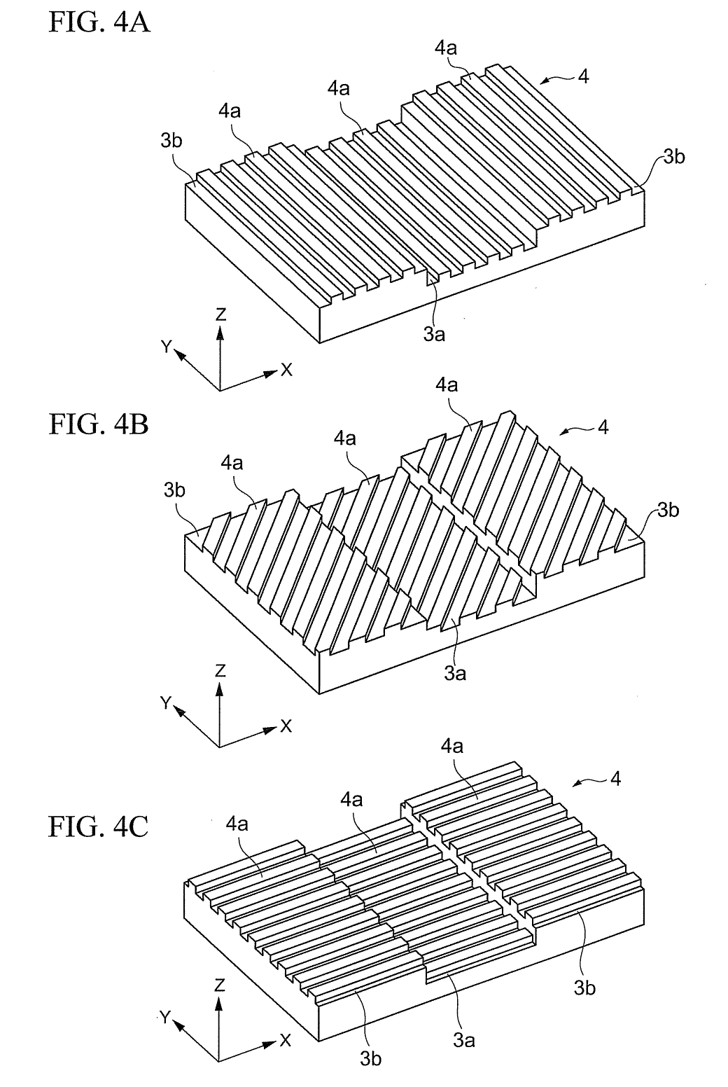

FIGS. 4A, 4B, and 4C are enlarged schematic perspective views partially showing the diffractive structure section 3 and the grid section 4.

Based on these figures, in the case where each of the micro protuberance portions 4a of the grid section 4 is a one-dimensional grid, a preferred aspect of the positional relationship between the diffractive structure section 3 and the grid section 4 will be described.

As the positional relationship between the diffractive structure section 3 and the grid section 4, an aspect shown, for example, in FIG. 4A can be adopted.

Specifically, in the example shown in FIG. 4A, each of the recessed portions 3a and each of the protuberance portions 3b of the diffractive structure section 3 extend along the Y direction shown in the figure. Also, the recessed portions 3a and the protuberance portions 3b are alternately arrayed along the X direction.

Similarly, each of the micro protuberance portions 4a of the grid section 4 is extended along the Y direction shown in the figure. Also, these micro protuberance portions 4a are alternately arrayed along the X direction.

That is, the extension direction of each of the recessed portions 3a and the extension direction of each of the protuberance portions 3b is parallel to the extension direction of the micro protuberance portion 4a.

Furthermore, in the positional relationship between the diffractive structure section 3 and the grid section 4, it is also preferable that the extension direction of each of the recessed portions 3a and the extension direction of each of the protuberance portions 3b be intersected at an angle with the extension direction of each of the micro protuberance portions 4a as shown in FIGS. 4B and 4C.

Specifically, in the example shown in FIG. 4B, each of the recessed portions 3a and each of the protuberance portions 3b of the diffractive structure section 3 are extended along the Y direction shown in the figure. Also, the recessed portions 3a and the protuberance portions 3b are alternately arrayed along the X direction.

In contrast, each of the micro protuberance portions 4a of the grid section 4 is extended along a direction that is intersected with the Y direction shown in the figure at an angle of approximately 45°. Also, these micro protuberance portions 4a are alternately arrayed along a direction orthogonal to the intersected direction.

In the example shown in FIG. 4C, each of the recessed portions 3a and each of the protuberance portions 3b of the diffractive structure section 3 are extend along the Y direction shown in the figure. Also, the recessed portions 3a and the protuberance portions 3b are alternately arrayed along the X direction.

In contrast, each of the micro protuberance portions 4a of the grid section 4 is extended along a direction (i.e., X direction) that is intersected with the Y direction shown in the figure at an angle of approximately 90°. Also, these micro protuberance portions 4a are alternately arrayed along a direction (i.e., Y direction) orthogonal to the intersected direction.

As described above, by intersecting each of the recessed portions 3a and the protuberance portions 3b with each of the micro protuberance portions 4a, it is possible to easily form the micro protuberance portions 4a adjacent to a step-difference between each of recessed portions 3a and each of protuberance portions 3b.

An angle at which the extension direction of each of the recessed portions 3a and each of the protuberance portions 3b is intersected with the extension direction of each of the micro protuberance portions 4a may be optionally set.

The 45° and 90° of the intersection angle described above as an example is the angle that is often used in a general optical system, and is thereby preferable.

Furthermore, since the structure in which each of the recessed portions 3a and the protuberance portions 3b are intersected with each of the micro protuberance portions 4a is adopted, it is possible to enhance the light utilization efficiency of the diffractive optical element 1.

Specifically, in the case of using incidence light of TM-polarization (polarization having an electric field whose direction is orthogonal to the extension direction of the micro protuberance portion 4a), 78.6% of efficiency of actual measurement value is obtained in the structure in which each of the recessed portions 3a and the protuberance portions 3b are intersected with each of the micro protuberance portions 4a at 45°. An efficiency of 78.5% is obtained in the structure in which each of the recessed portions 3a and the protuberance portions 3b are intersected with each of the micro protuberance portions 4a at 90°.

In contrast, 77.4% of light utilization efficiency of actual measurement value is obtained in the structure in which each of the recessed portions 3a and the protuberance portions 3b are parallel to each of the micro protuberance portions 4a.

In the structure in which each of the recessed portions 3a and the protuberance portions 3b are parallel to each of the micro protuberance portions 4a, it is believed that the difference between the foregoing efficiencies occurs because defects of formation of the micro protuberance portions 4a easily occur at a position adjacent to noncontiguous step-difference between the recessed portion 3a and the protuberance portion 3b.

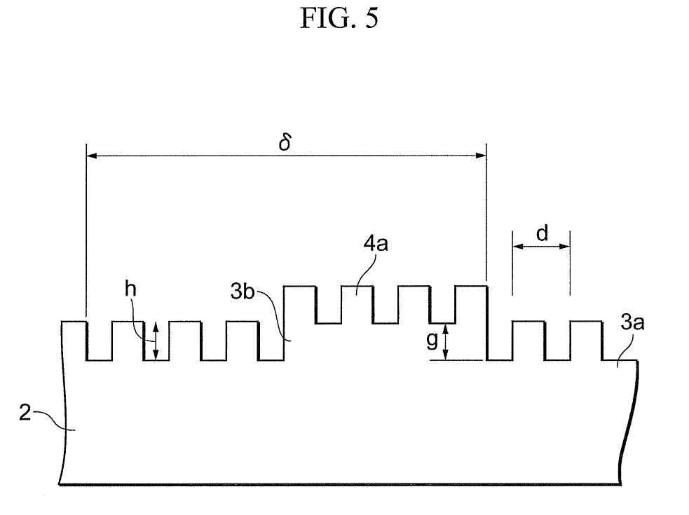

FIG. 5 is an enlarged schematic cross-sectional view showing the diffractive structure section 3 and a part of the grid section 4.

Furthermore, hatching is omitted as a matter of convenience for explanation.

The structure of the diffractive structure section 3 and the grid section 4 will be further described in detail based on FIG. 5.

As shown in the figure, the distance (period of irregularity structure) between each of the protuberance portions 3b of the diffractive structure section 3 corresponds to δ (nm), the distance (grid period) between each of the micro protuberance portions 4a of the grid section 4 corresponds to d (nm), and a wavelength of incidence light corresponds to λ (nm).

In the diffractive optical element 1 of this embodiment, a relationship between the wavelength λ of this incidence light, the diffractive structure, and the grid structure is consisted by formula (1) indicated below.

d<λ/n and λ<δ (1)

Here, n is the refractive index of the constituent material of the diffractive structure section 3.

In the case in which the material is quarts glass, the refractive index n is approximately 1.46 relative to visible light.

The case in which the diffractive optical element 1 is used for the light of wavelength of 532 nm is assumed, the above-described δ and d can be determined, for example, the d is 293 nm and the δ is 5.0 μm, respectively.

That is, the grid period d should be less than the value that is obtained by dividing the wavelength λ of the incidence light by the refractive index n.

In addition, the pitch δ of irregularity structure should be several times to ten times the wavelength λ of the incidence light.

Since these relationships are satisfied, it is possible to realize the micro protuberance portion 4a whose size is smaller than the protuberance portion 3b.

In addition, the depth h of the grid section 4 relative to the wavelength λ of the incidence light can be determined, for example, by formula (2) indicated below.

h=0.25λ/n_{eff} (2)

In this regard, n_{eff} is the equivalent refractive index relative to the wavelength λ in the grid section 4.

When the grid section 4 is formed by the foregoing conditions, it is possible to cause reflected light to be substantially zero by the grid section 4.

For example, when the λ is set to 532 nm, the n_{eff} becomes 1.25 in respect to linear polarization that is parallel to the grid, and the h is 108 nm.

In addition, a method for calculating the equivalent refractive index will be described later in detail in a second embodiment.

On the other, a preferred condition with regard to the depth g (the step-difference between the recessed portion 3a and the protuberance portion 3b) of the irregularity structure of the diffractive structure section 3 can be determined by formula (3) indicated below.

g=λ/2(n−1) (3)

In this regard, the refractive index of material of the diffractive structure section 3 is n.

Formula (3) means that the adequate depth relative to the wavelength λ exists.

For example, when the λ is set to 532 nm and n is set to 1.46, g is 578 nm.

Method for Manufacturing Diffractive Optical Element

The diffractive optical element 1 of this embodiment includes the above-described structure. Next, an example of a method for manufacturing the diffractive optical element 1 will be described.

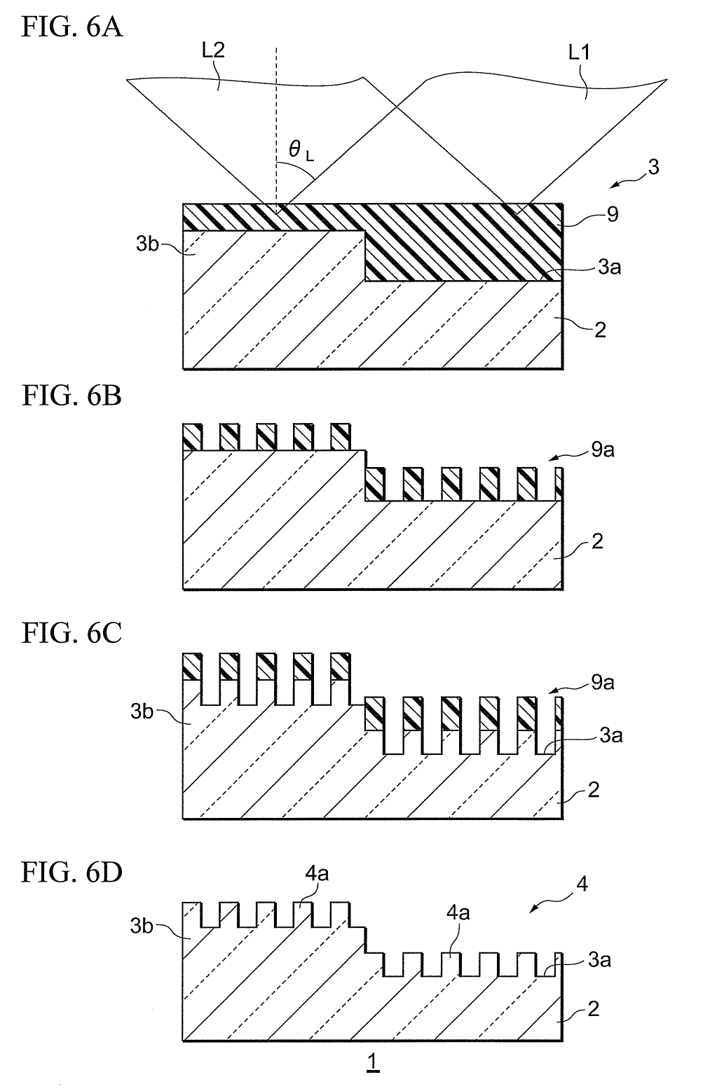

FIGS. 6A, 6B, 6C, and 6D are schematic flow sheets showing an example of a method for manufacturing the diffractive optical element 1.

A part of the cross-sectional face of the diffractive optical element 1 is enlarged and shown.

Firstly, the diffractive structure section 3 constituted of the recessed portions 3a and the protuberance portions 3b is formed on the first face of the substrate 2 (refer to FIG. 6A).

This process is realized by using, for example, a well-known photolithographic technique and an etching technique.

Specifically, at first, a photosensitive film (resist film or the like) is formed on the first face of the substrate 2. Next, this photosensitive film is exposed by using an exposure mask including an exposure pattern corresponding to each of the recessed portions 3a and the protuberance portions 3b, and this photosensitive film is developed.

Thereafter, a dry etching or a wet etching is performed by using the photosensitive film that has been developed, as an etching mask.

As a result, due to the pattern of the exposure mask, a predetermined irregularity is formed on the first face of the substrate 2.

Here, the substrate 2 is, for example, a quarts glass substrate as above-described, and whose thickness is, for example, 1.2 mm.

In addition, the step-difference (i.e., the depth g of the diffractive structure section 3) between the recessed portion 3a and the protuberance portion 3b is, for example, 578 nm as described above.

The depth g is controlled by controlling etching time or the like.

Next, the photosensitive film 9 covering the diffractive structure section 3 is formed on the first face of the substrate 2 (refer to FIG. 6A).

The photosensitive film 9 is, for example, a positive-type or a negative-type resist film.

The photosensitive film 9 can be formed using, for example, a spin coat method.

The thickness of the photosensitive film 9 may be adequately set. However, it is desirable that the photosensitive film 9 be formed so as to cover all of regions overlapping at least each of the recessed portions 3a and the protuberance portions 3b, so that the surface of the film as shown in the figure is substantially flat.

In this case, the difference between the thickness of the photosensitive film 9 on the upper portion (region corresponding to the protuberance portion 3b) of the diffractive structure section 3, and the thickness of the photosensitive film 9 on the bottom portion (region corresponding to the recessed portion 3a) of the diffractive structure section 3 is substantially equal to the above-described depth g of the diffractive structure section 3.

Next, the photosensitive film 9 formed on the first face of the substrate 2 is exposed by laser interference exposure (refer to FIG. 6A).

As a light source used for a laser interference exposure, a continuous oscillation DUV (Deep Ultra Violet) laser having wavelength of, for example, 266 nm is adopted.

The laser light output from this light source is appropriately separated into two laser lights L1 and L2, and the laser lights L1 and L2 are intersected with each other at the predetermined angle θ_{L}.

As a result, light (interfering light) including interference fringes is generated. The interference fringes are made of periodically bright and dark.

A pitch of interference fringes (period of bright and dark) is determined by the above-described intersection angle θ_{L}.

For example, the pitch of the interference fringes can be set to 293 nm by setting the intersection angle θ_{L} to 27°.

Due to irradiation of the photosensitive film 9 with the foregoing interfering light, the latent image pattern corresponding to the pitch of the interference fringes is formed on the photosensitive film 9.

Next, the photosensitive film 9 on which the latent image pattern is formed using the interfering light is developed (refer to FIG. 6B).

As a result, the photosensitive film pattern 9a having the pitch corresponding to the pitch of the interference fringes as shown in the figure.

For example, when the pitch of the interference fringes is set to 293 nm, the pitch of the photosensitive film pattern 9a becomes substantially 293 nm.

Next, an etching (e.g., example, dry etching) is performed using the photosensitive film pattern 9a as a mask (refer to FIG. 6C).

As a result, the pattern of the photosensitive film pattern 9a, as shown in the figure, is transferred onto the substrate 2.

Thereafter, the photosensitive film pattern 9a is removed (refer to FIG. 6D).

As a result, the grid section 4 (i.e., each of the micro protuberance portions 4a) is formed on the first face of the substrate 2, as shown in the figure, along the surface of each of the recessed portions 3a and the protuberance portions 3b of the diffractive structure section 3.

In the above-described FIGS. 6A, 6B, 6C, and 6D, the method for manufacturing the diffractive optical element including the grid section 4 that is a one-dimensional grid is described.

When the laser interference exposure is performed as shown in FIG. 6A, it is possible to manufacture the diffractive optical element including the grid section 4 as a two-dimensional grid and is formed by being exposed two times such that the relative position of the first face of the substrate 2 with respect to the interfering light is different by 90°.

Specifically, the laser interference exposure is performed two times while the relative position between the interfering light and the first face of the substrate 2 is changed, and it is thereby possible to form a latent image pattern that is shaped in a two-dimensional grid form on the photosensitive film 9.

Due to the etching with using the foregoing latent image pattern, it is possible to form the grid section 4 as a two-dimensional grid.

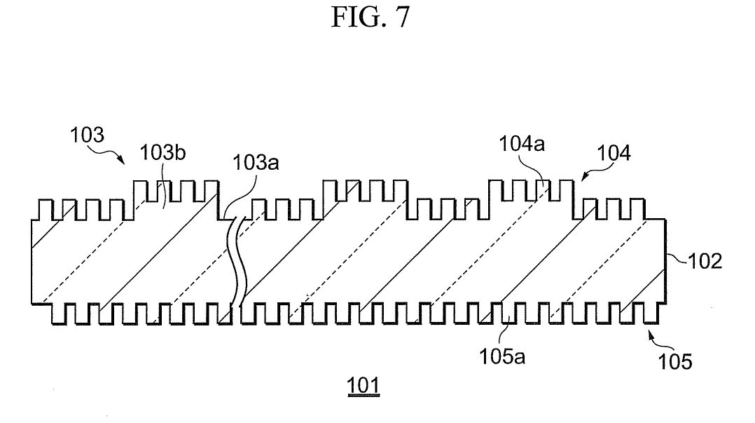

FIG. 7 is a schematic cross-sectional view showing a cross-sectional structure of a diffractive optical element of other embodiment.

A diffractive optical element 101 (optical element) shown in FIG. 7 includes a substrate 102, a diffractive structure section 103, a grid section 104 (non-diffractive structure section), and a grid section 105 (non-diffractive structure section).

The diffractive optical element 101 shown in FIG. 7 is different from the diffractive optical element 1 (refer to FIG. 1 or the other drawings) of the above-described embodiment in terms of that the grid section 105 is also formed on a back face of the substrate 102 (face on which the diffractive structure section 103 is not provided).

That is, in the diffractive optical element 101 of the embodiment shown in FIG. 7, a grid section 104 constituted of a plurality of micro protuberance portions 104 is formed on the first face of the substrate 102, and a grid section 105 constituted of a plurality of micro protuberance portions 105 is formed on a second face of the substrate 102.

According to the foregoing structure, reflected light that is reflected at any of the first face and the second face of the substrate 102 is also suppressed, and it is possible to reduce reflectance loss.

A method of manufacturing the foregoing diffractive optical element 101 is similar to the above-described embodiment (refer to FIGS. 6A, 6B, 6C, and 6D).

That is, each of the processes such as the exposure using the laser interference exposure, a developing, and an etching may be performed on both the first face and the second face of the substrate 102.

Furthermore, a grid section may be provided only on the second face of a substrate.

In this case, in the above-described diffractive optical element 101 shown in FIG. 7, the grid section 104 of the first face of the substrate 102 may be omitted.

In addition, the manufacturing method is also similar to the above-described embodiment (refer to FIGS. 6A, 6B, 6C, and 6D).

That is, each of processes such as the exposure using the laser interference exposure, a developing, and an etching may be performed on the second face of the substrate 102.

As described in detail above, in the diffractive optical element of the embodiment, the effect that the reflected light is suppressed occurs caused by action of the grid section, and the transmissive diffracted light includes an adequate and wide intensity distribution caused by action of the diffractive structure section.

By appropriately setting the arrangement of the irregularity of the diffractive structure section or the form in a plan view of the diffractive structure section, and it is thereby possible to control the formation and the intensity of the optical pattern depending on the purpose of use and the usage environment of the optical pattern caused by transmitted light.

That is, anti-reflective function and optical pattern production function are combined, and the diffractive optical element that has an anti-reflective means with a high level of resistance and that can also resist a high energy laser light is realized.

The diffractive optical element 1 including the above-described structure in this embodiment can be preferably used for, for example, an application for separating an incident laser beam into a plurality of beams, and an application for shaping a beam such as changing the energy distribution or the like.

In addition, due to anti-reflective function that is obtained by a sub-wavelength structure, reflectance loss of incidence light is reduced, and it is possible to achieve a high level of light utilization efficiency.

The foregoing diffractive optical element is especially suited for a case in which a film material which can be used as an adequate anti-reflective does not exist at the moment, or for a case in which light of ultraviolet light or infrared light is used.

The diffractive optical element of the above-described this embodiment can be used for various optical systems.

A laser beam machining method using the diffractive optical element and an example structure of a laser beam machining apparatus conducting the method will be described below as an example.

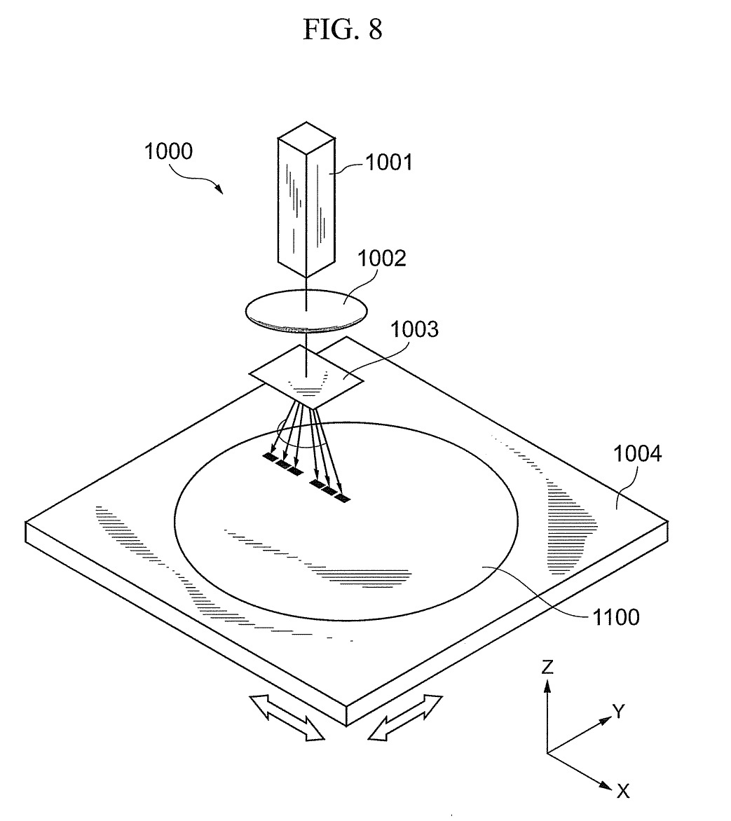

FIG. 8 is a schematic perspective view illustrating a structure of a laser beam machining apparatus of one embodiment.

The laser beam machining apparatus 1000 of this embodiment shown in FIG. 8 is configured to include a light source 1001, a lens 1002, a diffractive optical element 1003, and a stage 1004.

The substrate 1100 (base material) that is an object as a work is disposed on the stage 1004.

The substrate 1100 is, for example, a silicon wafer.

The light source 1001 is a device outputting a laser light.

For example, a Q-switch pulse laser can be used as the light source 1001.

In the light source 1001, for example, the power output is approximately 50 to 100 W, the pulse width is approximately 50 nm, and the pulse cycle period is approximately 1 kHz.

A laser light output from the light source 1001 is incident to the lens 1002 disposed in an optical axis of the laser light, and concentrated by the lens 1002.

The laser light that has been concentrated by the lens 1002 is incident to the diffractive optical element 1003 disposed in an optical axis of the laser light.

The diffractive optical element 1003 functions as a separating means that separates the laser light that has been incident thereto into a plurality of beams.

The diffractive optical element 1003 is preferably a diffract beam splitter in terms of light utilization efficiency and ease of use. However, the diffractive optical element 1003 is not limited to the diffract beam splitter.

As shown in the figure, by passing the laser light through the diffractive optical element 1003, a plurality of separated beams is generated.

Each of generated beams is emitted onto the substrate 1100 fixed on the stage 1004.

In the figure, the separated beams are drawn so that an angle at which the separated beam is incident to the substrate 1100 is greater than real angle of that for explanation.

Actually, each separated beam is incident at an angle close to substantially vertical.

The substrate 1100 is fixed on the stage 1004 (substrate transfer means) by vacuum contact or the like. The stage 1004 freely transfers the substrate 1100 in two directions (XY directions shown in the figure).

In addition, the stage 1004 also freely transfers the substrate 1100 in the Z direction orthogonal to the XY directions.

According to the laser beam machining method of the foregoing embodiment and the laser beam machining apparatus applying this method, when a plurality of places of an object is irradiated with the beam so that a variety of workings is performed, it is possible to sufficiently enhance the energy of the laser light to be incident thereinto.

The reason is that, due to the anti-reflective function by the grid section, it is possible to suppress stray light that causes damage to an optical system and an object (work piece).

As a result, it is possible to realize the laser beam machining with a high level of productivity and reliability.

Furthermore, by applying this laser beam machining method, it is possible to realize the laser beam machining apparatus with excellence cost performance.

The invention shall not be limited to the above-described embodiments. The invention may include various modifications of the embodiments in a scope of the spirit of the invention.

For example, the diffractive structure section is formed by working such as etching or the like on the first face of the substrate in the above-described embodiment. However, another manufacturing method can be adopted.

Specifically, it is also possible to form the same optical element as above described by forming a transparent polymer film (polymeric resin) through which a wavelength of light for use can pass on the first face of the substrate, thereafter, a photomask-exposure and a wet etching is performed on the polymer film.

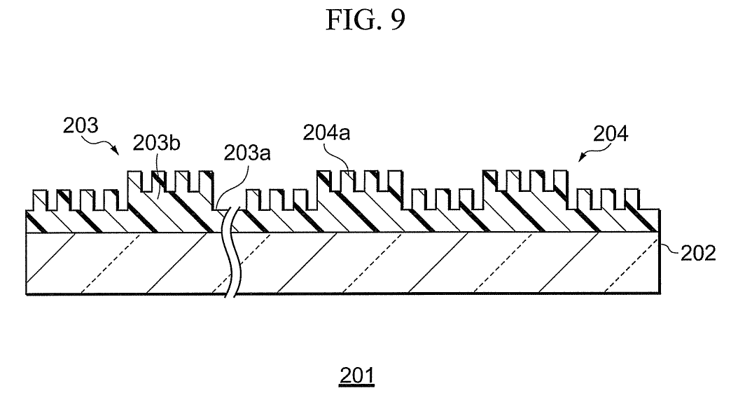

An example structure of the optical element formed by this method is shown in FIG. 9.

In an optical element 201 shown in FIG. 9, a diffractive structure section 203 and a grid section 204 that are formed using the polymer film are disposed on a first face of a substrate 202 made of glass or the like.

The diffractive structure section 203 includes recessed portions 203a and protuberance portions 203b. The grid section 204 constituted of a plurality of micro protuberance portions 204a is disposed along the surface of these recessed portions 203a and protuberance portions 203b.

Furthermore, also in the diffractive optical element 201 shown in FIG. 9, a grid section may be provided on both faces of the substrate similarly to the embodiment shown in FIG. 7.

In addition, other than description above, a substrate having a diffractive structure section may be formed so as to be an integral molding by using a glass which can be formed by a die forming, which has a high refractive index, and through which a wavelength of light for use can pass (n is equal to approximately 2.0).

In this case, since the refractive index is high, it is possible to make the depth g of a diffractive structure section smaller, and this case is preferable for forming a grid section.

In addition, a diffractive structure section can also be formed by forming other film (e.g., an inorganic film such as SiO₂ or the like) on a substrate, and by selectively etching this film.

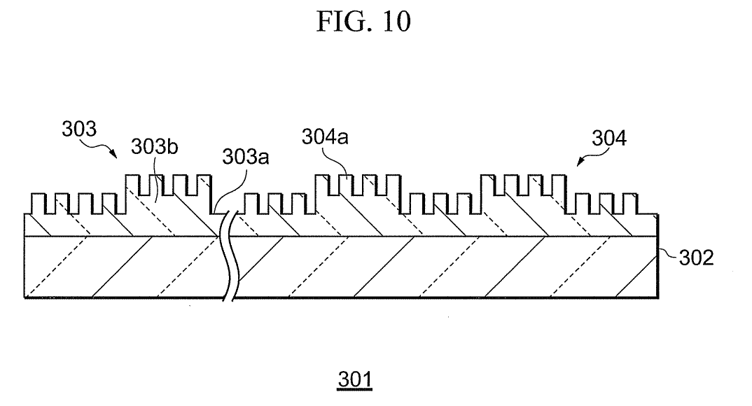

An example structure of the optical element formed by this method is shown in FIG. 10.

In an optical element 301 shown in FIG. 10, a diffractive structure section 303 that is formed using a film such as SiO₂ or the like is disposed on a first face of a substrate 302 made of glass or the like.

The diffractive structure section 303 includes recessed portions 303a and protuberance portions 303b. The grid section 304 constituted of a plurality of micro protuberance portions 304a is disposed along the surface of these recessed portions 303a and protuberance portions 303b.

Furthermore, also in the diffractive optical element 301 shown in FIG. 10, a grid section may be provided on both faces of the substrate in a manner similar to the embodiment shown in FIG. 7.

### Modified Example of Manufacturing Method

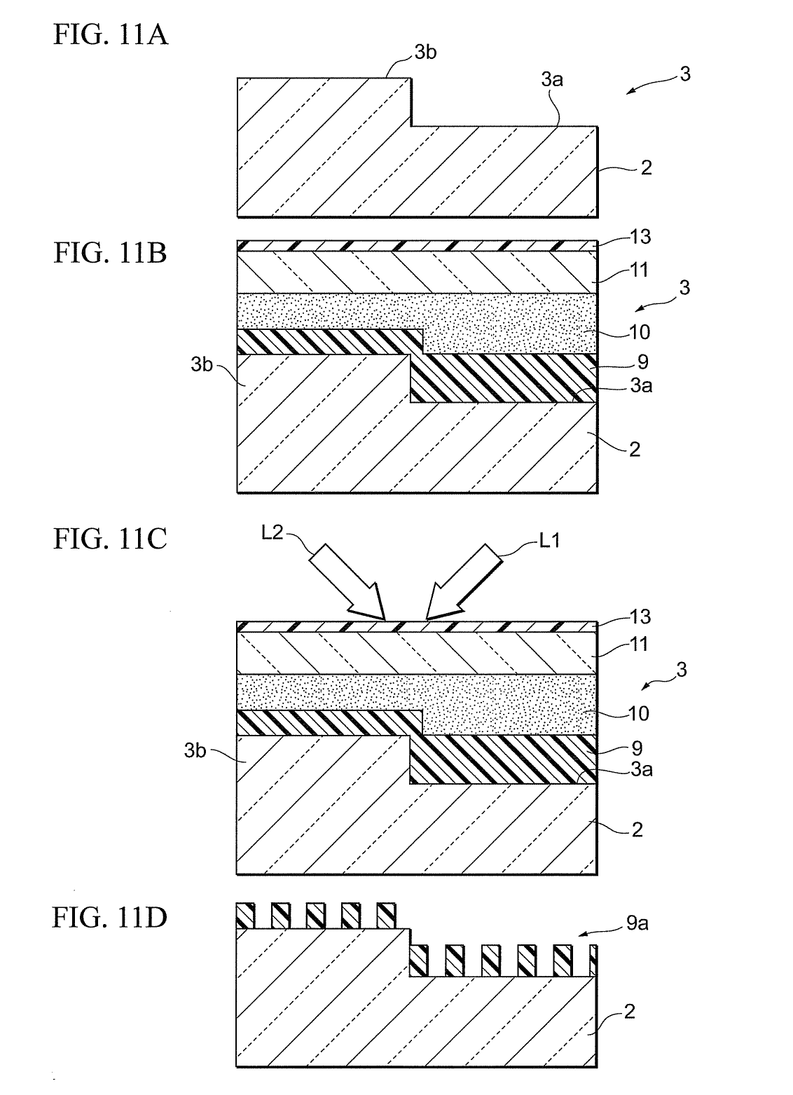

Next, a method for manufacturing a diffractive optical element of a first and a second modified example of the invention will be described with reference to FIGS. 11A, 11B, 11C, 11D, 12A, 12B, 13A, and 13B.

### First Modified Example

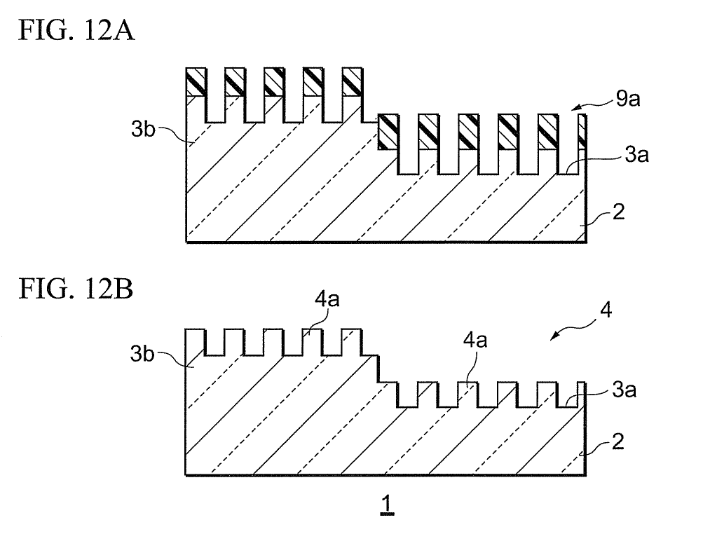

FIGS. 11A, 11B, 11C, 12A, and 12B are schematic flow sheets showing a method for manufacturing a diffractive optical element of a modified example.

A part of the cross-sectional face of the diffractive optical element 1 is enlarged and shown in these figures.

In the manufacturing method according to the modified example, firstly, the diffractive structure section 3 constituted of the recessed portions 3a and the protuberance portions 3b is formed on the first face of the substrate 2 (refer to FIG. 11A).

This process is similar to the process of the foregoing embodiment shown in FIG. 6A.

That is, at first, a photosensitive film (resist film or the like, not shown) is formed on the first face of the substrate 2. Next, this photosensitive film is exposed by using an exposure mask including an exposure pattern corresponding to each of the recessed portions 3a and the protuberance portions 3b, and this photosensitive film is developed.

Thereafter, a dry etching or a wet etching is performed by using the photosensitive film that has been developed, as an etching mask.

Therefore, due to the pattern of the exposure mask, a predetermined irregularity is formed on the first face of the substrate 2.

The substrate 2 is, for example, a quarts glass substrate as described above and whose thickness is, for example, 1.2 mm.

In addition, the step-difference (i.e., the depth of the diffractive structure section 3) between the recessed portion 3a and the protuberance portion 3b is, for example, 578 nm as described above.

The depth g is controlled by controlling etching time or the like.

Next, the photosensitive film 9 covering the diffractive structure section 3 is formed on the first face of the substrate 2 (refer to FIG. 11B).

The photosensitive film 9 is, for example, a positive-type of negative-type resist film.

The photosensitive film 9 can be formed by, for example, a spin coat method.

The thickness of the photosensitive film 9 may be adequately set. However, it is desirable all of flat regions of the substrate 2 including at least each of the recessed portions 3a and the protuberance portions 3b be covered with the photosensitive film 9, and so that the surface of the film is substantially flat.

However, the evenness of the surface of the photosensitive film 9 may be low as shown in the figure, caused by the recessed portions 3a and the protuberance portions 3b that are on the bottom side of the photosensitive film 9.

Next, the liquid (liquiform film) 10 having a high refractive index and covering the photosensitive film 9 is formed, and a transparent parallel plate (substrate) 11 is disposed so as to face to the substrate 2 with the liquid 10 interposed therebetween (refer to FIG. 11B).

The liquid 10 is sandwiched between the parallel plate 11 and the substrate 2, the liquid 10 is held on the photosensitive film 9 as shown in the figure.

It is desirable that the face of parallel plate 11 that is in contact with at least the liquid 10 have a high evenness (e.g., several nm order).

The parallel plate 11 is constituted of, for example, a quarts glass substrate.

In addition, as shown in the figure, it is preferable that the parallel plate 11 include an anti-reflective film 13 on a face into which a plurality of laser beams described below is incident.

The anti-reflective film 13 is, for example, a dielectric multilayer film or the like.

Here, as the liquid 10, liquid whose refractive index is greater than 1 and is less than or substantially equal to the refractive index of the photosensitive film 9 is used.

As the liquid 10, for example, liquid that has a high refractive index and is used in liquid-immersion lithography in manufacture of a semiconductor device can be used.

The refractive index of the liquid 10 in this case is, for example, approximately 1.53.

In addition, the refractive index of the photosensitive film 9 is, for example, approximately 1.70. The refractive index of the parallel plate 11 is, for example, approximately 1.50.

It is desirable that the refractive index of the liquid 10 is as close as possible to the refractive index of the photosensitive film 9.

In addition, the refractive index indicated in each example is the value when using a laser whose wavelength is 266 nm described below.

Next, the photosensitive film 9 formed on the first face of the substrate 2 is exposed by laser interference exposure via the above-described liquid 10 and the parallel plate 11 (refer to FIG. 11C).

As a light source used for a laser interference exposure, a continuous oscillation DUV (Deep Ultra Violet) laser having a wavelength of, for example, 266 nm is adopted.

The laser light output from this light source is appropriately separated into two laser lights L1 and L2, and the laser lights L1 and L2 are intersected with each other at the predetermined angle θ_{L}.

As a result, light (interfering light) including interference fringes is generated. The interference fringes are made of periodically bright and dark.

A pitch of interference fringes (period of bright and dark) is determined by the above-described intersection angle.

The pitch of the interference fringes can be set to 293 nm by setting the intersection angle θ_{L} to an appropriate angle.

Due to irradiation of the photosensitive film 9 with the foregoing interfering light, the latent image pattern corresponding to the pitch of the interference fringes is formed on the photosensitive film 9.

As described above, in the case where the anti-reflective film 13 is formed on the parallel plate 11, the reflected light generated at the interface between the air layer and the parallel plate 11 is suppressed, and it is possible to further reduce irregularities of exposure.

In addition, in various values of accuracy required in the diffractive optical element 1 as a micro-structure, in the case where the diffractive optical element 1 includes a specified value of accuracy, it is conceivable that a certain level of irregularity of exposure may be allowed.

In addition, in balance that is made by the refractive indexes of the parallel plate 11, the liquid 10, and the photosensitive film 9, in the case where a balance is obtained under a specified condition, it is conceivable that the reflected light generated at the interface between the air layer and the parallel plate 11 is suppressed without a practical problem.

Therefore, the providing of the anti-reflective film 13 on the parallel plate 11 is not essential.

Next, the photosensitive film 9 on which the latent image pattern is formed using the interfering light is developed (refer to FIG. 11D).

Therefore, the photosensitive film pattern 9a having the pitch corresponding to the pitch of the interference fringes as shown in the figure.

For example, when the pitch of the interference fringes is set to 293 nm, the pitch of the photosensitive film pattern 9a becomes substantially 293 nm.

Next, an etching (e.g., example, dry etching) is performed using the photosensitive film pattern 9a as a mask (refer to FIG. 12A).

Therefore, the pattern of the photosensitive film pattern 9a as shown in the figure is transferred onto the substrate 2.

Thereafter, the photosensitive film pattern 9a is removed (refer to FIG. 12B).

Therefore, the grid section 4 (i.e., each of the micro protuberance portions 4a) is formed on the first face of the substrate 2 as shown in the figure along the surface of each of the recessed portions 3a and the protuberance portions 3b of the diffractive structure section 3.

In the above-described FIGS. 11A, 11B, 11C, 12A, and 12B, the method for manufacturing the diffractive optical element including the grid section 4 that is a one-dimensional grid is described. It is possible to manufacture the diffractive optical element including the grid section 4 as a two-dimensional grid similar to the case of the foregoing embodiment.

That is, when the laser interference exposure is performed as shown in FIG. 11C, the exposure is performed two times such that the relative position of the first face of the substrate 2 with respect to the interfering light is different by 90°.

Specifically, the laser interference exposure is performed two times while the relative position between the interfering light and the first face of the substrate 2 is changed, and it is thereby possible to form a latent image pattern that is shaped in a two-dimensional grid form on the photosensitive film 9.

Due to the etching with using the foregoing latent image pattern, it is possible to form the grid section 4 as a two-dimensional grid.

### Second Modified Example

In addition, in the manufacturing method of the above-described first modified example, the liquid 10 having a high refractive index is held using the parallel plate 11.

However, a water soluble film having a high refractive index can be used instead of the liquid 10.

Therefore, it is possible to omit the use of the parallel plate 11.

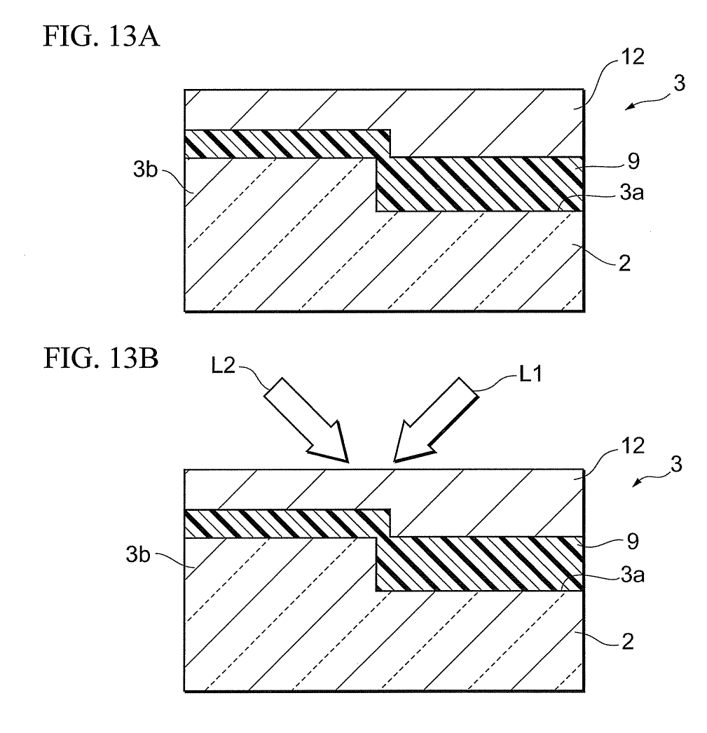

As described below, as a manufacturing method of the second modified example, a manufacturing method in which a water soluble film is used will be described with reference to FIGS. 13A and 13B.

FIGS. 13A and 13B are schematic flow sheets showing, for example, a method for manufacturing a diffractive optical element.

Deferent points from the manufacturing method of the first modified example shown in FIGS. 11A, 11B, 11C, 12A, and 12B are only described below, and common portions shown in these figures are omitted.

Firstly, the diffractive structure section 3 constituted of the recessed portions 3a and the protuberance portions 3b is formed on the first face of the substrate 2 (refer to FIG. 11A), and the photosensitive film 9 covering the diffractive structure section 3 is formed (refer to FIG. 11B) in a manner similar to the manufacturing method of the first modified example.

Thereafter, a water soluble film 12 is formed on the photosensitive film 9 (refer to FIG. 13A).

The water soluble film 12 is formed by, for example, a spin coat method.

It is possible to relax the step-difference formed on the surface of the photosensitive film 9 by appropriately adjusting the viscosity or the like of the water soluble film 12.

As the foregoing water soluble film, an anti-reflective film used for applying onto a surface of a photo-resist, for example, called “TSP series” provided by TOKYO OHKA KOGYO CO., LTD can be used.

The parallel plate 11 of the first modified example is not necessary by using the water soluble film 12.

As the water soluble film 12, a film whose refractive index is greater than 1 and is less than or substantially equal to the refractive index of the photosensitive film 9 is used.

For example, the refractive index of the water soluble film 12 is substantially in a range from 1.40 to 1.50.

It is desirable that the refractive index of the water soluble film 12 is as close as possible to the refractive index of the photosensitive film 9.

Next, the photosensitive film 9 formed on the first face of the substrate 2 is exposed by laser interference exposure via the water soluble film 12 (refer to FIG. 13B).

The conditions of the laser interference exposure are similar to the foregoing first modified example.

In addition, a two-dimensional grid may be formed by performing the laser interference exposure two times.

Next, the photosensitive film 9 is developed (refer to FIG. 11D).

In this time, since the water soluble film 12 also has the water solubility, it is possible to easily remove the water soluble film 12.

Specifically, the water soluble film 12 may be removed prior to development of the photosensitive film 9, and the photosensitive film 9 can be developed without removal of the water soluble film 12.

That is, the removal of the water soluble film 12 before development of the photosensitive film 9 is not essential.

When the developing is performed while the water soluble film 12 is provided, a pattern is formed on the photosensitive film 9, and it is possible to also dissolve the water soluble film 12 at the same time.

Next, an etching is performed using the obtained photosensitive film pattern 9a as a mask (refer to FIG. 12A). The pattern of the photosensitive film pattern 9a is transferred onto the substrate 2.

Thereafter, the photosensitive film pattern 9a is removed (refer to FIG. 12B).

As a result, the grid section 4 (i.e., each of the micro protuberance portions 4a) is formed on the first face of the substrate 2 along the surface of each of the recessed portions 3a and the protuberance portions 3b of the diffractive structure section 3.

As described in detail above, in the manufacturing method of the first and the second modified example, the laser interference exposure is performed in such a manner in that the liquid whose refractive index is greater than that of air is disposed on the photosensitive film, or the water soluble film that is similar to the liquid is disposed on the photosensitive film.

Comparing this case with the case where interfering light is directly incident into the photosensitive film (i.e., the case of exposing in a manner in that the photosensitive film is in contact with air), the difference of the refractive index between the photosensitive film and a medium (liquid and parallel plate) that is in contact with the photosensitive film becomes low due to disposing the liquid or the water soluble film.

Therefore, diffraction of interfering light caused by irregularities formed on the surface of the photosensitive film is suppressed. Irregularities of intensity distribution of the interfering light in the photosensitive film can be prevented.

Therefore, according to the manufacturing method of the modified example, exposure is reliably realized on the surface whose evenness is low caused by forming the recessed portions 3a and the protuberance portions 3b, and it is possible to manufacture a diffractive optical element with a high quality.

### Second Embodiment

Next, a diffractive optical element of a second embodiment of the invention will be described with reference to the drawings.

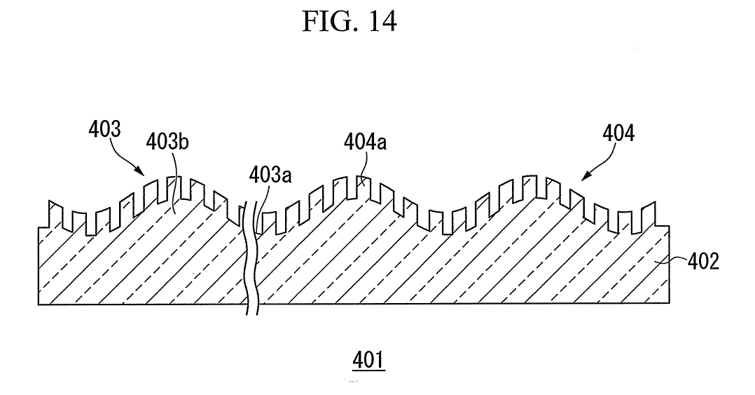

FIG. 14 is a schematic cross-sectional view showing a cross-sectional structure of the diffractive optical element of the second embodiment.

The diffractive optical element 401 of this embodiment shown in FIG. 14 includes a substrate 402, a diffractive structure section 403, and a grid section 404 (non-diffractive structure section).

The substrate 402, that is similar to the substrate 2 of the first embodiment, is a transparent substrate through which a wavelength of incidence light can pass.

The diffractive structure section 403 is provided on a first face of the substrate 402.

A second face (opposite face relating to the diffractive structure section 403) of the substrate 2 is a plane as shown in the figure.

The diffractive structure section 403 includes recessed portions 403a and protuberance portions 3b that are formed on the first face of the substrate 402.

The diffractive structure section 403 constituted of recessed portions 403a and protuberance portions 403b is shaped in a curved surface form. The cross-sectional form of the curved surface form of the diffractive structure section 403 is a continuously and smoothly curved line as shown in the figure.

In this embodiment, the diffractive structure section 403 is formed by working a first face of the substrate 402.

That is, the substrate 402 and the diffractive structure section 403 are constituted so as to become one body.

The grid section 404 is provided on the first face of the substrate 402 and along an upper face of the diffractive structure section 403.

The grid section 404 of this embodiment is formed so as to be unified with the above-described substrate 402 and the diffractive structure section 403.

This grid section 404 includes a plurality of micro protuberance portions 404a. The size of the micro protuberance portion 404a is smaller than each of the protuberance portions 403b of the above-described diffractive structure section 403.

Each of the micro protuberance portions 404a is made of a dielectric material.

In this embodiment, the constituent material of each micro protuberance portion 404a is a quarts glass.

Each of the micro protuberance portions 404a of the grid section 404 may be a structure body with a stripe form (one-dimensional grid) extending in one direction (the Y direction shown in figure) as indicated in the grid section 4 shown in FIG. 2A for example, and may be arrayed in a matrix form (two-dimensional grid) as shown in FIG. 2B.

The distance between each of the micro protuberance portions 404a may be constant. Alternatively, it is not necessary for the distance to be constant.

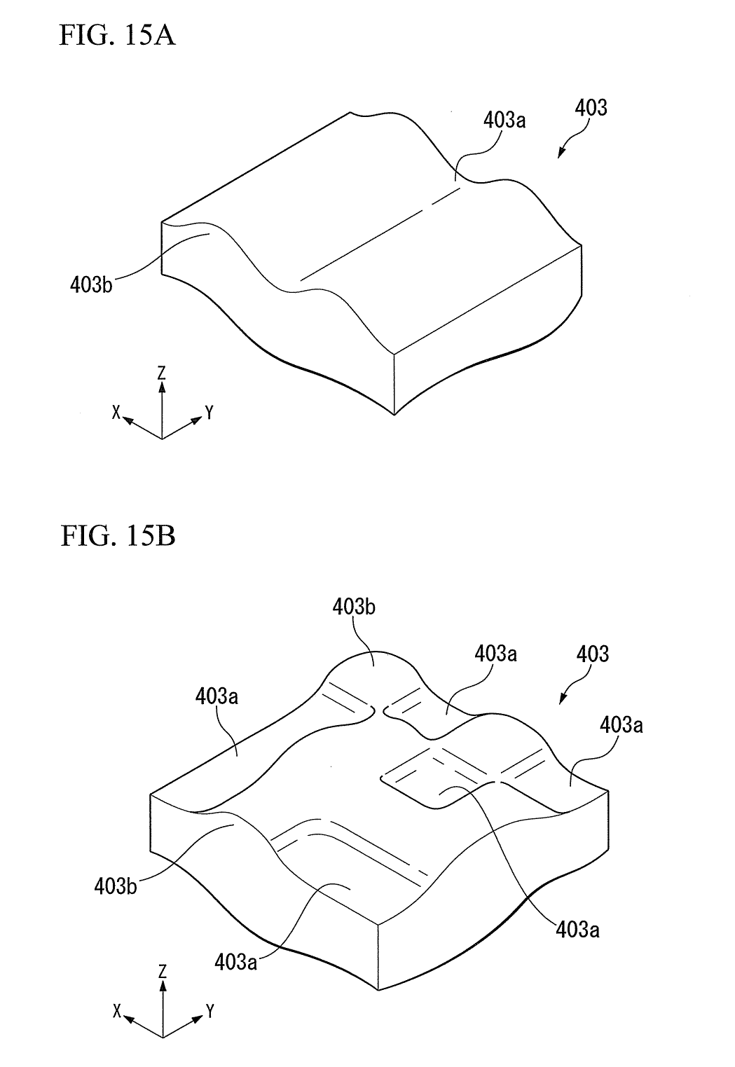

FIGS. 15A and 15B are enlarged schematic perspective views showing a part of the diffractive structure section 403.

As shown in FIG. 15A, the diffractive structure section 403 includes recessed portions 403a and protuberance portions 403b that are extended in one direction (the Y direction shown in the figure).

These recessed portions 403a and the protuberance portions 403b are shaped in a stripe form as shown in the figure and are periodically arrayed along the X direction.

Furthermore, each of the recessed portions 403a and the protuberance portions 403b is not limited to a one-dimensional arrangement (one-dimensional grid) as shown in FIG. 15A. Each of the recessed portions 403a and the protuberance portions 403b may be a two-dimensional arrangement (two-dimensional grid) as shown, for example, in FIG. 15B.

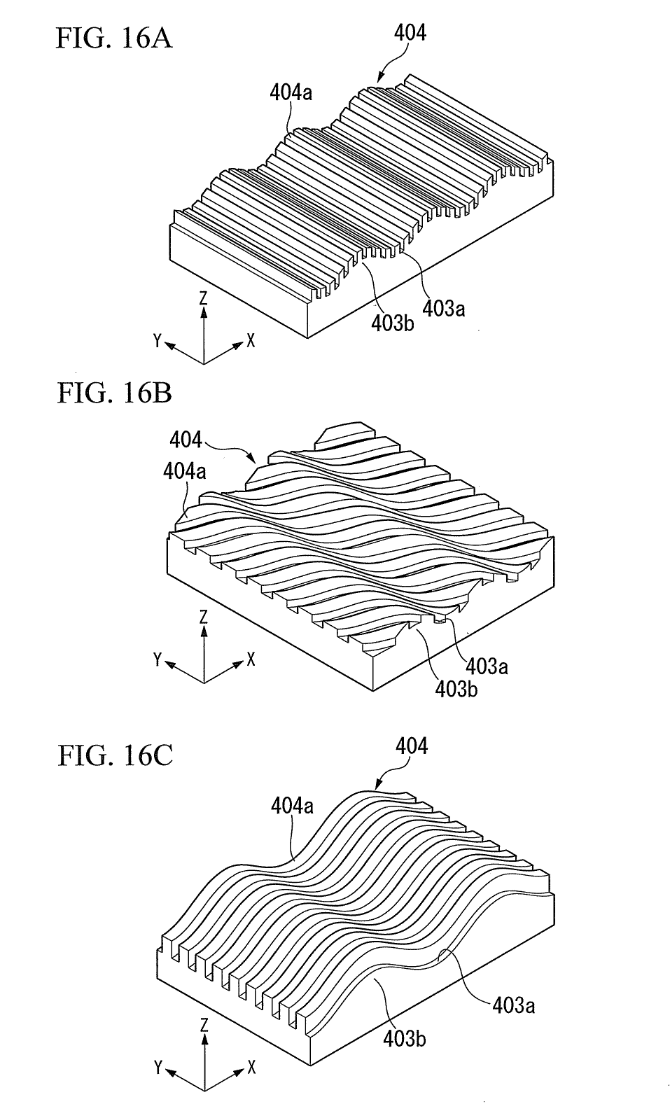

FIGS. 16A, 16B, and 16C are enlarged schematic perspective views partially showing the diffractive structure section 403 and the grid section 404.

As shown in each of FIGS. 16A, 16B, and 16C, in the diffractive optical element 401 of this embodiment, each of the aspects shown in FIGS. 16A, 16B, and 16C can be adopted for the positional relationship between the diffractive structure section 403 and the grid section 404.

In an example of the diffractive structure section 403 shown in FIG. 16A, each of the recessed portions 403a and each of the protuberance portions 403b extend along the Y direction as shown in the figure. Also, the recessed portions 403a and the protuberance portions 3b are arrayed along the X direction.

Similarly, in the grid section 404, each of the micro protuberance portions 404a is extended along the Y direction shown in the figure. Also, these micro protuberance portions 4a are arrayed along the X direction.

Therefore, the extension directions of the recessed portions 403a and the extension direction of each of the protuberance portions 403b are parallel to the extension direction of the micro protuberance portion 4a.

In addition, in the positional relationship between the diffractive structure section 403 and the grid section 404, the extension directions of the recessed portions 403a and the protuberance portions 403b may be intersected with the extension direction of the micro protuberance portion 404a as shown in FIGS. 16B and 16C.

In an example of the diffractive structure section 403 shown in FIG. 16B, each of the recessed portions 403a and the protuberance portions 403b is extended along the Y direction as shown in the figure. Also, the recessed portions 403a and the protuberance portions 403b are arrayed along the X direction.

In contrast, in the grid section 404, the micro protuberance portions 4a extend in a direction that is intersected with the Y direction shown at an angle of 45° in the figure.

The micro protuberance portions 4a are arrayed along the direction orthogonal to the direction that is intersected with the Y direction.

In an example of the diffractive structure section 403 shown in FIG. 16C, the recessed portions 403a and the protuberance portions 403b that extend in the Y direction shown in the figure are arrayed along the X direction.

In contrast, in the grid section 404, the micro protuberance portions 404a extend in a direction that is intersected with the Y direction shown at an angle of approximately 90° (i.e., X direction) in the figure. The micro protuberance portions 404a are alternately arrayed along the direction (i.e., Y direction) orthogonal to the direction that is intersected with the Y direction.

By adopting the arrangement shown in FIGS. 16B and 16C, the micro protuberance portion 404a that is adjacent to a step-difference between the recessed portion 403a and the protuberance portion 403b is easily formed. In addition, desired optical characteristics (anti-reflectivity) of the grid section 404 are easily obtained.

An angle at which the extension direction of the recessed portion 403a and the protuberance portion 403b is intersected with the extension direction of the micro protuberance portions 4a may be optionally set.

The 45° and 90° of the intersection angle described above as an example is the angle that is often used in a general optical system, and is thereby preferable.

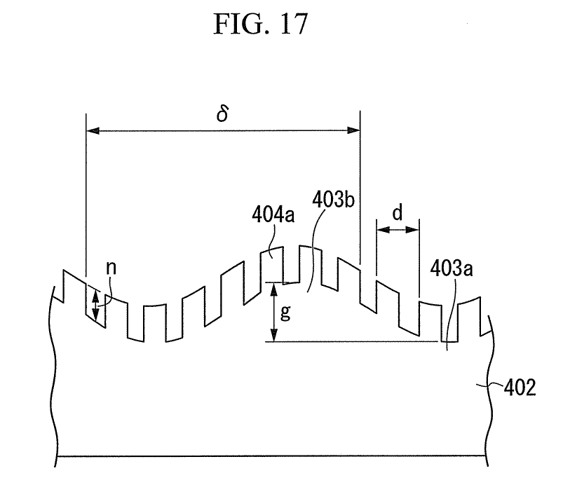

Next, the structure of the diffractive structure section 403 and the grid section 404 will be further described in detail based on FIG. 17.

FIG. 17 is an enlarged schematic cross-sectional view showing the diffractive structure section 403 and a part of the grid section 404.

Furthermore, hatching is omitted as a matter of convenience for explanation.

As shown in the figure, the distance (period of irregularity structure) between the protuberance portions 403b of the diffractive structure section 403 corresponds to δ (nm), the distance (grid period) between the micro protuberance portions 404a of the grid section 404 corresponds to d (nm), and the wavelength of incidence light corresponds to λ (nm).

In the diffractive optical element 401 of this embodiment, the relationship between the wavelength λ of this incidence light, the diffractive structure, and the grid structure, is as defined below in formula (4).

d<λ/n and λ<δ (4)

Here, n is the refractive index of constituent material of the diffractive structure section 403.

In the case in which the material is quarts glass, the refractive index n is approximately 1.46 relative to visible light.

In addition, light is vertically incident into the diffractive optical element 401.

That is, the grid period d should be less than the value that is obtained by dividing the wavelength λ of the incidence light by the refractive index n.

In addition, the pitch δ of irregularity structure should be a value greater than the wavelength λ of the incidence light.

These relationships are satisfied, so it is thereby possible to realize the micro protuberance portion 404a whose size is smaller than the protuberance portion 403b.

In addition, the depth h of the grid section 404 relative to the wavelength λ of the incidence light can be determined, for example, by formula (5) indicated below.

h=0.25λ/n_{eff} (5)

In this regard, n_{eff} is the equivalent refractive index relative to the wavelength λ in the grid section 4, and is a value that is determined by formulas (6) and (7) described below.

n(TE)=√[f·e1+(1−f)·e2] (6)

n(TM)=1/√[f/e1+(1−f)/e2] (7)

In this regard, the n (TE) means the equivalent refractive index (=n_{eff}) with regard to TE-polarization (the direction of an electric field is the extension direction of the micro protuberance portion 404a). The n (TM) means the equivalent refractive index (=n_{eff}) with regard to TM-polarization.

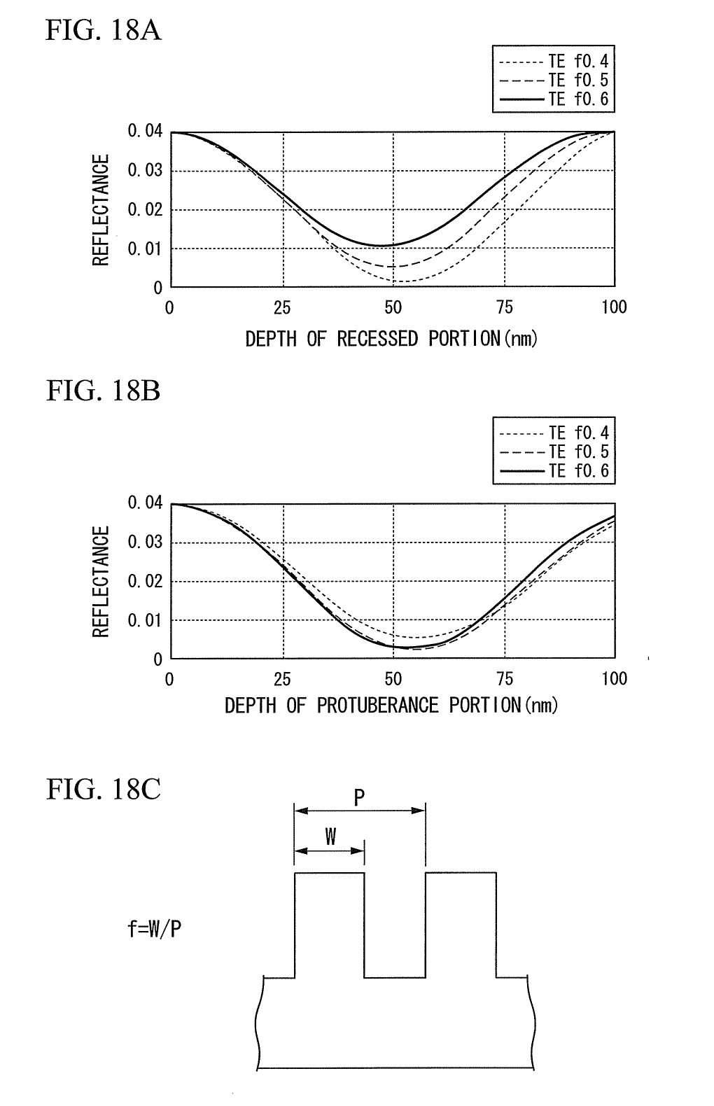

In addition, reference numeral f is the filling rate of the grid section 404, and formula f=w/P using the pitch P and the width w of the micro protuberance portion 404a is expressed (refer to FIG. 18C).

In addition, reference numeral e1 means the dielectric constant of the grid section 404, and reference numeral e2 means the dielectric constant of a medium surrounding the grid section 404.

For example, if a wavelength λ=266 nm of the ultraviolet light that is incident into the diffractive optical element 401 is assumed, the δ, d, and h are respectively determined to be, for example, 376 μm, 140 nm, and 52 nm, based on formulas (4) to (7) (TE-polarization).

When the grid section 404 is formed under the foregoing conditions, it is possible to reduce the amount of reflected light to be substantially zero caused by the grid section 404.

Here, FIG. 18A is a diagram illustrating an example of the relationship between reflectance of a diffractive optical element 401 in the case of using incidence light of TE-polarization, and the depth of a recessed portion (the height of micro protuberance portion 404a) of a grid section 404.

FIG. 18B is a diagram illustrating an example of the relationship between reflectance and the depth of the recessed portion, in the case of using incidence light of TM-polarization.

FIGS. 18A and 18B are diagrams illustrating reflectance in respect to the depth of the recessed portion and the depth of the protuberance portion in the case where the grid section 404 is the one-dimensional grid shown in FIG. 2A. The diagrams of FIGS. 18A and 18B are rigorously calculated by a coupled-wave analysis under the condition where the grid section 404 is rectangular in a cross-sectional view thereof.

As shown in FIG. 18B, it is understood that reflectance is approximately zero in an adjacent area where the depth of the recessed portion of the grid section 404 is 55 nm in respect to TM-polarization.

That is, in the diffractive optical element 401 of this embodiment, since one-dimensional rectangular grid is adopted and the polarization conditions of incidence light are specified, it is possible to achieve non-reflection, even if the grid whose depth is less than 100 nm is shallow (the height of the grid is low).

In contrast, preferred coition with regard to the depth g (the step-difference between the recessed portion 403a and the protuberance portion 403b) of the irregularity structure of the diffractive structure section 403 can be determined by formula (8).

g≧λ/(n−1) (8)

In this regard, the n is the refractive index of material of the diffractive structure section 403.

Formula (8) means that adequate depth with regard to the wavelength λ exists.

For example, when λ is 266 nm and n is 1.50, g is greater than or equal to 532 nm.

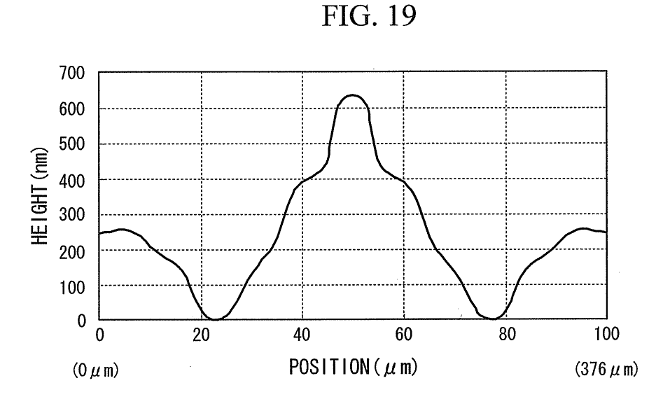

Here, FIG. 19 is a diagram illustrating an example of a cross-sectional form of the diffractive structure section 403.

FIG. 19 corresponds to a cross-sectional form of the diffractive structure section 403 in the X direction shown in FIG. 15A, and indicates one-period of irregularity structure of the diffractive structure section 403.

That is, the diffractive structure section 403 of this example has the cross-sectional form in which the curved line shown in FIG. 19 is periodically continued in the X direction shown in FIG. 15A. The diffractive structure section 403 of this example is the one-dimensional grid having the curved surface form in which the periodical cross-sectional form is evenly continued in the Y direction.

As shown in the figure, the diffractive structure section 403 of this embodiment has the cross-sectional form formed of the continuously and smoothly curved line. The depth of the cross-sectional form is 636 nm.

When a laser light is caused to be incident to the diffractive structure section 403 of the cross-sectional structure shown in FIG. 19, the laser light is separated into thirteen beams (−6 order light to 6 order light) whose intensities are substantially equal to each other.

The ideal light utilization efficiency is 97%.

The cross-sectional form of the diffractive structure section 403 shown in FIG. 19 can be designed by a method for developing the cross-sectional form with a sin functional waveform (or cos functional waveform), by recurrently optimizing the combination of coefficient of each term so as to achieve the required splitter performance (refer to Reference document 1).

Parameters for designing are number of waveforms, amplitude, and phase.

In the case where the number of beams separated by the diffractive structure section 403 is N (odd number), the number of functional waveforms that are considerable for designing is at least _{N}C₂.

These waveforms are harmonic components of an interference field that is obtained by overlapping the N numbers of planar waves.

Here, the N numbers of planar waves correspond to the diffract beams constituted of the beams whose orders are from the order represented by “−(N−1)/2” to the order represented by “+(N−1)/2”.

The interference field is expressed as a complex number, and the phase component of the complex number becomes the cross-sectional form of the diffractive structure section 403.

In order to obtain an optimal combination of the above-described design parameters, the inventor uses a simulated annealing method (refer to Reference document 2).

In this method, designing depends on a combination of the design parameters and the annealing conditions.

That is, since a plurality of cross-sectional forms obtaining splitter performances that are equal to each other exists, a form that is easily formed is selected from the cross-sectional forms.

When selecting the form, a form with an irregularity structure as shallow as possible, and without the portions that are partially formed (e.g., the portions whose depthes are varied in a discontinuous manner) is desired.

In calculation for the intensity of the diffracted light, a discrete Fourier transform is used.

In the case of this example, since the irregularity structure of the diffractive structure section 403 is sufficiently thin (shallow), diffract efficiency is calculated by a scalar theory without any trouble. It is actually confirmed that the difference between a scalar prediction and a vector prediction is small.

Reference document 1: D. Prongue, H. P. Herzig, R. Dandliker, and M. T. gale: Appl. Opt. 31 (1992) 5706.

Reference document 2: M. N. Vesperinas, R. Navarro, and F. J. Fuentes: J. Opt. Soc. A. A5 (1988) 30.

Method for Manufacturing Diffractive Optical Element

The diffractive optical element 401 of this embodiment includes the structure described above. Next, an example of a method for manufacturing the diffractive optical element 401 will be described.

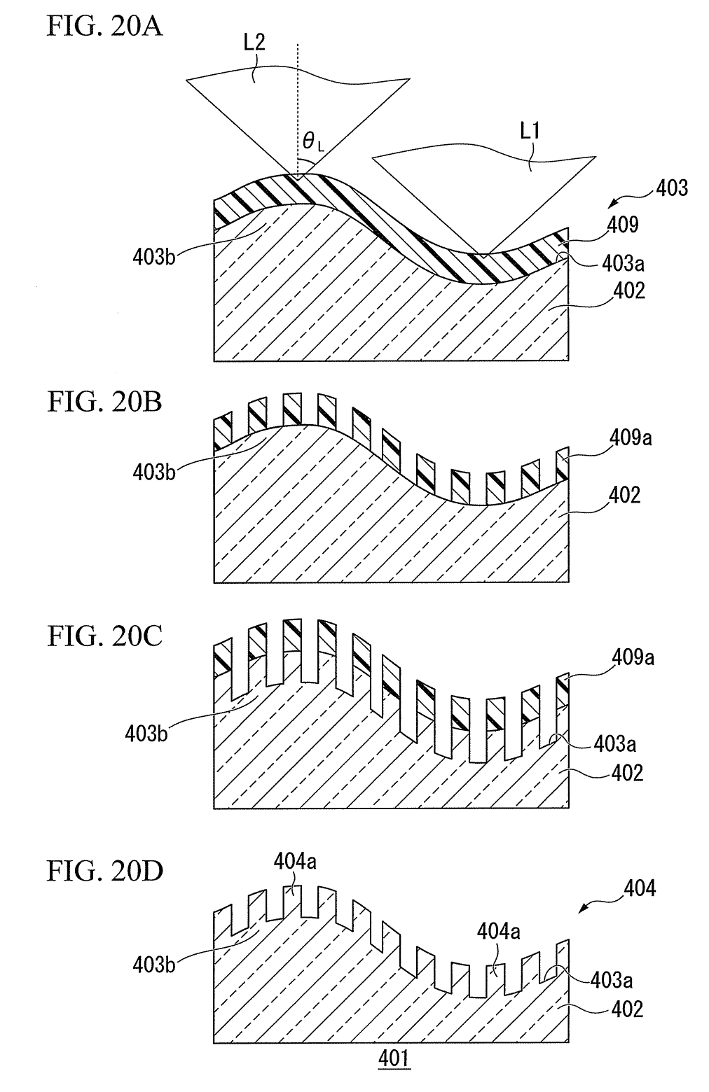

FIGS. 20A, 20B, 20C, and 20D are schematic flow sheets showing an example of a method for manufacturing the diffractive optical element 401.

A part of the cross-sectional face of the diffractive optical element 401 is enlarged and shown in FIGS. 20A, 20B, 20C, and 20D.

Firstly, the diffractive structure section 403 constituted of recessed portions 403a and protuberance portions 403b is formed on the first face of the substrate 402 (refer to FIG. 20A).

This process is realized by, for example, an etching technique using a mask formed by a laser drawing method, or a machining technique for cutting with a high level of precision.

In the case where the diffractive structure section 403 is formed using a laser drawing method, firstly, positive-type resist film is applied onto the substrate 402, the positive-type resist film is irradiated with a concentrated beam of a Kr laser (wavelength 413 nm), and the curved surface form that has been designed already is drawn.

The thickness of the concentrated beam is 0.50 μm, the drawing pitch is 0.10 μm.

According to the laser beam machining apparatus having the above-described structure, an external modulator modulates the intensity of a beam with high speed modulation, and it is thereby possible to draw a pattern with 256 steps of gradation sequence.

Next, an ion etching is performed after the drawing of a resist pattern, and the resist pattern is transferred to the substrate 402. Therefore, it is possible to form the diffractive structure section 403 on the first face of the substrate 402 by the transferring of the resist pattern.

In the case where the diffractive structure section 403 is formed by the above-described manufacturing method, it is preferable that a resist film whose y value of the characteristic curve regarding residue film is relatively low be used.

By using the foregoing resist, the exposure region in which linearity is high can be widely ensured, and it is possible to obtain a sufficient number of gradation sequences.

Here, the substrate 402 is, for example, a quarts glass substrate, and whose thickness is, for example, 1.2 mm.

In addition, the step-difference (i.e., the depth g of the diffractive structure section 403) between the recessed portion 403a and the protuberance portion 403b is, for example, 636 nm.

This depth g can be controlled by the mask shape that is formed using a laser drawing method, etching time, or the like.

Next, the photosensitive film 409 covering the diffractive structure section 403 is formed on the first face of the substrate 402 (refer to FIG. 20A).

The photosensitive film 409 is, for example, a positive-type or a negative-type resist film.

The photosensitive film 409 can be formed by, for example, a spin coat method.

The thickness of the photosensitive film 409 may be adequately set. However, it is desirable that all of regions overlapping at least each of the recessed portions 403a and the protuberance portions 403b be covered with the photosensitive film 409, so that the surface of the film as shown in the figure is substantially flat.

In this case, the difference between the thickness of the photosensitive film 409 on the upper portion (region corresponding to the protuberance portion 403b) of the diffractive structure section 403, and the thickness of the photosensitive film 409 on the bottom portion (region corresponding to the recessed portion 403a) of the diffractive structure section 403 is substantially equal to the above-described depth g of the diffractive structure section 403.

Next, the photosensitive film 409 formed on the first face of the substrate 402 is exposed by laser interference exposure (refer to FIG. 20A).

As a light source used for a laser interference exposure, a continuous oscillation DUV (Deep Ultra Violet) laser having a wavelength of, for example, 266 nm is adopted.

The laser light output from this light source is appropriately separated into two laser lights L1 and L2, and the laser lights L1 and L2 are caused to intersect with each other at a predetermined angle θ_{L}.

As a result, light (interfering light) including interference fringes is generated. The interference fringes are made of periodically bright and dark.

A pitch of interference fringes (period of bright and dark) is determined by the above-described intersection angle θ_{L}.

For example, the pitch of the interference fringes can be set to 140 nm by setting the intersection angle θ_{L} to 72°.

Due to irradiation of the photosensitive film 409 with the foregoing interfering light, the latent image pattern corresponding to the pitch of the interference fringes is formed on the photosensitive film 409.

Next, the photosensitive film 409 on which the latent image pattern is formed using the interfering light is developed (refer to FIG. 20B).

As a result, the photosensitive film pattern 409a having the pitch corresponding to the pitch of the interference fringes as shown in the figure.

For example, when the pitch of the interference fringes is set to 140 nm, the pitch of the photosensitive film pattern 9a becomes substantially 140 nm.

Next, an etching (e.g., example, dry etching) is performed using the photosensitive film pattern 409a as a mask (refer to FIG. 6C).

Therefore, the pattern of the photosensitive film pattern 409a as shown in the figure is transferred onto the substrate 402.

Thereafter, the photosensitive film pattern 409a is removed (refer to FIG. 20D).

As a result, the grid section 404 (i.e., each of the micro protuberance portions 404a) is formed on the first face of the substrate 402 as shown in the figure along the surface of each of the recessed portions 403a and the protuberance portions 403b of the diffractive structure section 403.

In the above-described FIGS. 20A, 20B, 20C, and 20D, the method for manufacturing the diffractive optical element including the grid section 404 that is a one-dimensional grid is described.

When the laser interference exposure is performed as shown in FIG. 20A, it is possible to manufacture the diffractive optical element including the grid section 404 as a two-dimensional grid and is formed by being exposed two times such that the relative position of the first face of the substrate 402 with respect to the interfering light is different by 90°.

Specifically, the laser interference exposure is performed two times while the relative position between the interfering light and the first face of the substrate 402 is changed, and it is thereby possible to form a latent image pattern that is shaped in a two-dimensional grid form on the photosensitive film 409.

Due to the etching with using the foregoing latent image pattern, it is possible to form the grid section 404 as a two-dimensional grid.

Furthermore, the manufacturing method of the foregoing first modified example and second modified example may be applied to the manufacture of the diffractive optical element 401 of the second embodiment.

Therefore, diffraction of interfering light caused by irregularities formed on the surface of the photosensitive film is suppressed. Irregularities of intensity distribution of the interfering light in the photosensitive film can be prevented.

Therefore, by adopting the manufacturing method of the modified example, exposure is reliably realized on the surface whose evenness is low caused by forming the recessed portions 403a and the protuberance portions 403b are formed, and it is possible to manufacture a diffractive optical element of a high quality.

As described in detail above, in the diffractive optical element 401 of this embodiment, an effect that the reflected light is suppressed occurs caused by action of the grid section 404, and the transmissive diffracted light includes an adequate and wide intensity distribution caused by action of the diffractive structure section 403.

By appropriately setting the arrangement of the irregularity of the diffractive structure section 403 and the form in a plan view of the diffractive structure section 403, it is possible to control the formation and the intensity of the optical pattern depending on the purpose of use and the usage environment of the optical pattern caused by transmissive diffracted light.

That is, anti-reflective function and optical pattern production function are combined in the diffractive optical element 401. The diffractive optical element 401 is a diffractive optical element having an anti-reflective means that can resist a high energy laser light.

In addition, since the diffractive optical element 401 of this embodiment includes the diffractive structure section 403 having the irregularity structure shaped in a continuously and smoothly curved surface form, it is possible to realize a high level of light utilization efficiency compared with the diffractive optical element 1 of the first embodiment including the diffractive structure section 3 that is rectangular in a cross-sectional view thereof.

Specifically, light utilization efficiency of the diffractive optical element 1 of the first embodiment is approximately 78% (theoretical value). In contrast, in the diffractive optical element 401 of the second embodiment, it is possible to achieve approximately 97% (theoretical value) light utilization efficiency.

The reason is that, noncontiguous step-difference is formed at a border between the recessed portions 3a and the protuberance portions 3b in the first embodiment of the diffractive structure section 3 that is rectangular in a cross-sectional view thereof, high order diffracted light appears because this step-difference has a high spatial frequency component, and incidence light energy leaks as a high order diffracted light.

In contrast, in the diffractive optical element 401 of the second embodiment, the diffractive structure section 403 is shaped in a smooth curved surface form, high order diffracted light is sufficiently weak, and it is possible to emit substantially all energy as a desired diffracted light.

In addition, in the diffractive optical element 401 of the second embodiment, the height of the micro protuberance portion 404a in the grid section 404 can be low, and a high manufacturability can thereby be obtained.

Furthermore, specifically, in the case where the height of the micro protuberance portion 404a is great, it is necessary to form deep grooves on the substrate 402 in the process shown in FIG. 20C, the photosensitive film pattern 409a having great thickness should be formed in FIG. 20B.

In this manner, irregularities of exposure easily occur when exposing the photosensitive film 409, and the photosensitive film pattern 409a becomes elongated in a direction of the thickness thereof. Therefore, the photosensitive film pattern 409a may be easily inclined.

As a result, the heights of the micro protuberance portions 404a formed on the substrate 402 may easily be nonuniform.

In contrast, in the case where the height of the micro protuberance portion 404a is low, that is, the height of the micro protuberance portions 404a are less than 200 nm, the photosensitive film 409 can be thin and uniformly exposed.

In addition, in this case, the photosensitive film pattern 409a can also maintain a stance in which the photosensitive film pattern 409a stands vertically up on the substrate 402.

Therefore, it is possible to form the micro protuberance portions 404a having regular height with a high level of precision.

The diffractive optical element 401 of the above-described second embodiment can be also used for various optical systems similar to the diffractive optical element 1 of the first embodiment.

For example, the diffractive optical element 401 of the above-described second embodiment can be preferably used in the laser beam machining method described in the first embodiment with reference to FIG. 8 and the laser beam machining apparatus for conducting this method.

Furthermore, by using the diffractive optical element 401 of the second embodiment, when a plurality of places of an object is irradiated with the beam so that a variety of workings is performed, it is possible to further enhance the energy of the laser light to be incident.

As a result, it is possible to realize the laser beam machining with a high level of productivity and reliability.

Furthermore, by applying this laser beam machining method, it is possible to realize a laser beam machining apparatus with excellence cost performance.

Furthermore, in the diffractive optical element 401 of this embodiment, since the intensity of the high order diffracted light is sufficiently weak, damages caused by the high order diffracted light does not occur in a work (work piece), and there is an advantage that a shading mask for blocking off high order diffracted light to be incident to a work is unnecessary.

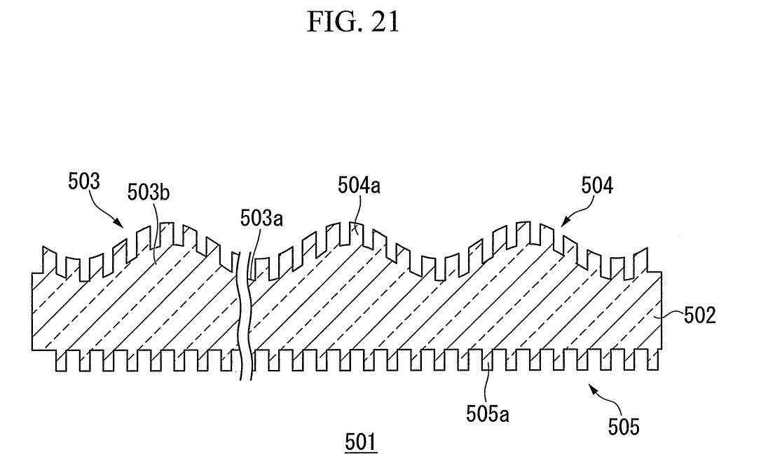

Next, FIG. 21 is a schematic cross-sectional view showing an aspect of other structure of a diffractive optical element of the second embodiment.

A diffractive optical element 501 (optical element) shown in FIG. 21 includes a substrate 502, a diffractive structure section 503, a grid section 504 (non-diffractive structure section), and a grid section 505 (non-diffractive structure section).

The diffractive optical element 501 shown in FIG. 21 is different from the diffractive optical element 401 (refer to FIG. 14 or the other drawings) of the second embodiment in that the grid section 505 is also formed on a back face of the substrate 502 (face on which the diffractive structure section 503 is not provided).

That is, in the diffractive optical element 501 of the embodiment shown in FIG. 21, a grid section 504 constituted of a plurality of micro protuberance portions 504 is formed on the first face of the substrate 502, and a grid section 505 constituted of a plurality of micro protuberance portions 505 is formed on a second face of the substrate 502.

According to the foregoing structure, reflected light that is reflected at any of the first face and the second face of the substrate 502 is also suppressed, and it is possible to reduce reflectance loss.

A method for manufacturing the foregoing diffractive optical element 501 is similar to the above-described embodiment (refer to FIGS. 20A, 20B, 20C, and 20D).

That is, each process such as the exposure using the laser interference exposure, a developing, and an etching may be performed on both the first face and the second face of the substrate 502.

Furthermore, the grid section may be provided only on the second face of the substrate.

In this case, in the above-described diffractive optical element 501 shown in FIG. 21, the grid section 504 of the first face of the substrate 502 may be omitted.

In addition, the manufacturing method is also similar to the above-described embodiment (refer to FIGS. 20A, 20B, 20C, and 20D).

That is, each process such as the exposure using the laser interference exposure, a developing, and an etching may be performed on the second face of the substrate 502.

Furthermore, in the second embodiment, other manufacturing method can also be adopted.

Specifically, it is also possible to form the same optical element as above described by forming a transparent polymer film (polymeric resin) through which a wavelength of light for use can pass on the first face of the substrate, thereafter, a photomask-exposure and a wet etching are performed on the polymer film.

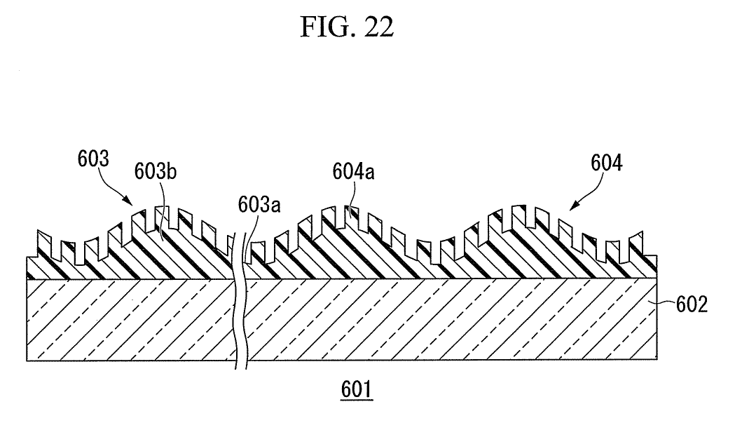

An example structure of the optical element formed by this method is shown in FIG. 22.

In an optical element 601 shown in FIG. 22, a diffractive structure section 603 and a grid section 604 that are formed using the polymer film are disposed on a first face of a substrate 602 made of glass or the like.

The diffractive structure section 603 includes recessed portions 603a and protuberance portions 603b. The grid section 604 constituted of a plurality of micro protuberance portions 604a is disposed along the surface of these recessed portions 603a and protuberance portions 603b.

Furthermore, also in the diffractive optical element 601 shown in FIG. 22, a grid section can be provided on both faces of the substrate similarly to the embodiment shown in FIG. 21.

In addition, other than description above, a substrate having a diffractive structure section may be formed so as to be an integral molding by using a glass which can be formed by a die forming, which has a high refractive index, and through which a wavelength of light for use can pass (n is equal to approximately 2.0).

In this case, since the refractive index is high, it is possible to make the depth g of a diffractive structure section smaller, and this case is preferable for forming a grid section.

In addition, a diffractive structure section can also be formed by forming other film (e.g., an inorganic film such as SiO₂ or the like) on a substrate, and by selectively etching this film.

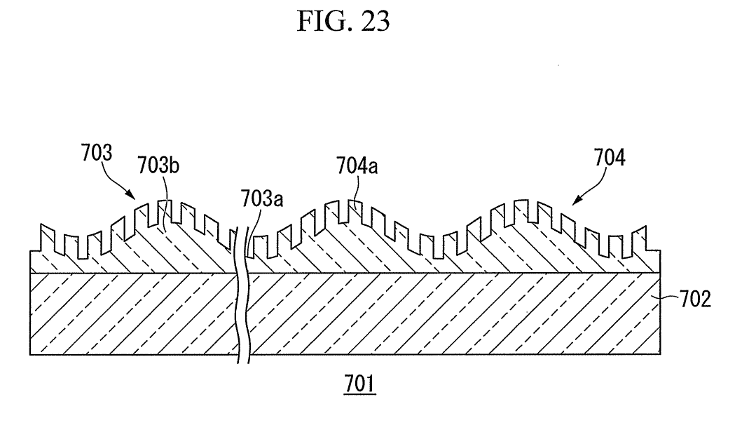

An example structure of the optical element formed by this method is shown in FIG. 23.

In an optical element 701 shown in FIG. 23, a diffractive structure section 703 that is formed using a film such as SiO₂ or the like is disposed on a first face of a substrate 702 made of glass or the like.

The diffractive structure section 703 includes recessed portions 703a and protuberance portions 703b. The grid section 704 constituted of a plurality of micro protuberance portions 704a is disposed along the surface of these recessed portions 703a and protuberance portions 703b.

Furthermore, also in the diffractive optical element 701 shown in FIG. 23, a grid section can be provided on both faces of the substrate similarly to the embodiment shown in FIG. 21.

What is claimed is:

1. A diffractive optical element comprising:
a substrate having a first face and a second face;
a diffractive structure section that is formed on the first face of the substrate, shaped in a rectangular form in a cross-sectional view of the diffractive structure section, and having an upper face and a plurality of protuberance portions; and
a grid section that is formed of a dielectric material, formed on at least one of the upper face of the diffractive structure section and the second face of the substrate, and including micro protuberance portions that are smaller than each of the protuberance portions.

2. The diffractive optical element according to claim 1, wherein
each of the micro protuberance portions of the grid section is extended in one direction.

3. The diffractive optical element according to claim 2, wherein
an extension direction of each protuberance portion of the diffractive structure section is substantially parallel to an extension direction of each micro protuberance portion of the grid section.

4. The diffractive optical element according to claim 2, wherein
an extension direction of each protuberance portion of the diffractive structure section is intersected with an extension direction of each micro protuberance portion of the grid section.

5. The diffractive optical element according to claim 1, wherein
each of the micro protuberance portions of the grid section is arrayed so as to be two-dimensionally distributed.

6. The diffractive optical element according to claim 1, wherein
the depth of the grid section is less than the depth of the diffractive structure section.

7. The diffractive optical element according to claim 1, wherein
the diffractive structure section separates the incidence light into a plurality of beams.

8. A laser beam machining method comprising:
preparing a diffractive optical element including:
a substrate having a first face and a second face,
a diffractive structure section that is formed on the first face of the substrate, shaped in a rectangular form in a cross-sectional view of the diffractive structure section, having an upper face and a plurality of protuberance portions, and is capable of separating light that is incident into the diffractive structure section into a plurality of beams, and
a grid section that is formed of a dielectric material, formed on at least one of the upper face of the diffractive structure section and the second face of the substrate, and including micro protuberance portions that are smaller than each of the protuberance portions; and
causing a laser light to be incident into the diffractive optical element so that the laser light is separated into a plurality of beams and so that an object is irradiated with the beams.

9. A diffractive optical element comprising:
a substrate having a first face and a second face;
a diffractive structure section including an upper face and a plurality of protuberance portions that is formed on the first face of the substrate and shaped in a periodic curved surface form; and
a grid section that is formed on at least one of the upper face of the diffractive structure section and the second face of the substrate, and including micro protuberance portions that are smaller than each of the protuberance portions.

10. The diffractive optical element according to claim 9, wherein
each of the micro protuberance portions of the grid section is extended in one direction.

11. The diffractive optical element according to claim 10, wherein
an extension direction of each protuberance portion of the diffractive structure section is substantially parallel to an extension direction of each micro protuberance portion of the grid section.

12. The diffractive optical element according to claim 10, wherein
an extension direction of each protuberance portion of the diffractive structure section is intersected with an extension direction of each micro protuberance portion of the grid section.

13. The diffractive optical element according to claim 9, wherein
each of the micro protuberance portions of the grid section is arrayed so as to be two-dimensionally distributed.

14. The diffractive optical element according to claim 9, wherein
the depth of the grid section is less than the depth of the diffractive structure section.

15. The diffractive optical element according to claim 9, wherein
the diffractive structure section separates the incidence light into a plurality of beams.

16. A laser beam machining method comprising:
preparing a diffractive optical element including:
a substrate having a first face and a second face,
a diffractive structure section that includes an upper face and a plurality of protuberance portions that is formed at a position which is close to the first face of the substrate and shaped in a periodic curved surface form, and is capable of separating light that is incident into the diffractive structure section into a plurality of beams, and
a grid section that is formed on the at least one of the upper face of the diffractive structure section and the second face of the substrate, and including micro protuberance portions that are smaller than each of the protuberance portions; and
causing a laser light to be incident into the diffractive optical element so that the laser light is separated into a plurality of beams and so that an object is irradiated with the beams.

17. A method for manufacturing a diffractive optical element, comprising:
preparing a substrate having a first face and a second face;
forming a plurality of protuberance portions on the first face;
forming a photosensitive film covering the protuberance portions on the first face;
disposing liquid so as to cover the photosensitive film with the liquid whose refractive index is greater than 1 and is less than or equal to the refractive index of the photosensitive film;
disposing a transparent parallel plate so as to face to the substrate with the liquid interposed therebetween;
exposing the photosensitive film via the parallel plate and the liquid;
developing the photosensitive film after removing the liquid and the parallel plate;
etching the substrate using a pattern of the photosensitive film as a mask; and
obtaining a diffractive optical element including:
a diffractive structure section having a plurality of protuberance portions formed on the first face of the substrate, and
a grid section that is formed of a dielectric material, formed on an upper face of the diffractive structure section, and including micro protuberance portions that are smaller than each of the protuberance portions.

18. The method according to claim 17, wherein
the parallel plate includes an anti-reflective film formed on a face of the parallel plate into which light exposing the photosensitive film is incident.

19. A method for manufacturing a diffractive optical element, comprising:
preparing a substrate having a first face and a second face;
forming a plurality of protuberance portions on the first face;
forming a photosensitive film covering the protuberance portions on the first face;
disposing a water soluble film so as to cover the photosensitive film with the water soluble film whose refractive index is greater than 1 and is less than or equal to a refractive index of the photosensitive film;
exposing the photosensitive film via the water soluble film;
developing the photosensitive film;
etching the substrate using a pattern of the photosensitive film as a mask; and
obtaining a diffractive optical element including:
a diffractive structure section having a plurality of protuberance portions formed on the first face of the substrate, and
a grid section that is formed of a dielectric material, formed on an upper face of the diffractive structure section, and including micro protuberance portions that are smaller than each of the protuberance portions.

20. The method according to claim 19, wherein
the developing of the photosensitive film is performed after removing the water soluble film.
